(19) United States
(12) Patent Application Publication
(10) Pub. No.: US 2026/0088061 A1
(43) Pub. Date: Mar. 26, 2026

(54) SEMICONDUCTOR MEMORY DEVICE

(71) Applicant: Kioxia Corporation, Tokyo (JP)

(72) Inventors: Nobuyoshi SAITO, Ota Tokyo (JP); Takafumi MASUDA, Yokkaichi Mie (JP); Mutsumi OKAJIMA, Yokkaichi Mie (JP); Kazuki ESHIRO, Yokohama Kanagawa (JP)

(73) Assignee: Kioxia Corporation, Tokyo (JP)

(21) Appl. No.: 19/076,776

(22) Filed: Mar. 11, 2025

(30) Foreign Application Priority Data
Sep. 20, 2024 (JP) 2024-163216

(51) Int. Cl. G11C 5/06; H10B 51/10; H10B 51/20; H10B 53/10; H10B 53/20

(52) U.S. Cl. CPC G11C 5/063; H10B 51/10; H10B 51/20; H10B 53/10; H10B 53/20

(57) ABSTRACT

A semiconductor memory device includes: semiconductor layers stacked in a first direction and arranged in a second direction and a third direction; via-wirings each electrically connected to the semiconductor layers stacked in the first direction; memory portions electrically connected to the semiconductor layers; gate electrodes opposed to the semiconductor layers; and wiring members each disposed between two gate electrodes adjacent in the third direction among the gate electrodes. The plurality of gate electrodes include first gate electrodes disposed at a first position in the first direction and arranged in the third direction. The wiring members include first wiring members disposed at the first position in the first direction and arranged in the third direction. The first wiring members are mutually electrically connected via the first gate electrodes.

### CROSS-REFERENCE TO RELATED APPLICATIONS

This application is based upon and claims the benefit of Japanese Patent Application No. 2024-163216, filed on Sep. 20, 2024, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a semiconductor memory device according to a first embodiment;

FIG. 2 is a schematic perspective view illustrating a configuration of a part of the semiconductor memory device;

FIG. 3 is a schematic perspective view illustrating a configuration of a part of the semiconductor memory device;

FIG. 4 is a schematic XY cross-sectional view illustrating a configuration of a part of a memory layer ML;

FIG. 5 is a schematic XY cross-sectional view illustrating a configuration of a part of the memory layer ML;

FIG. 6 is a schematic XZ cross-sectional view illustrating a configuration of a part of the memory layer ML;

FIG. 7 is a schematic XY cross-sectional view illustrating a configuration of a part of the memory layer ML;

FIG. 8 is a schematic XZ cross-sectional view illustrating a configuration of a part of the memory layer ML;

FIG. 9 is a schematic cross-sectional view for describing a method of manufacturing the semiconductor memory device according to the first embodiment;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic XY cross-sectional view illustrating a configuration of a part of a semiconductor memory device according to a second embodiment;

FIG. 66 is a schematic XY cross-sectional view illustrating a configuration of a part of the semiconductor memory device according to the second embodiment;

FIG. 67 is a schematic XZ cross-sectional view illustrating a configuration of a part of the semiconductor memory device according to the second embodiment;

FIG. 68 is a schematic XY cross-sectional view illustrating a configuration of a part of a semiconductor memory device according to a third embodiment;

FIG. 69 is a schematic cross-sectional view for describing a method of manufacturing the semiconductor memory device according to the third embodiment;

FIG. 70 is a schematic cross-sectional view for describing the manufacturing method;

FIG. 71 is a schematic cross-sectional view for describing the manufacturing method;

FIG. 72 is a schematic XY cross-sectional view illustrating a configuration of a part of a semiconductor memory device according to a fourth embodiment;

FIG. 73 is a schematic XZ cross-sectional view illustrating a configuration of a part of the semiconductor memory device according to the fourth embodiment;

FIG. 74 is a schematic XY cross-sectional view illustrating a configuration of a part of a semiconductor memory device according to a fifth embodiment;

FIG. 75 is a schematic XY cross-sectional view illustrating a configuration of a part of the semiconductor memory device according to the fifth embodiment;

FIG. 76 is a schematic XZ cross-sectional view illustrating a configuration of a part of the semiconductor memory device according to the fifth embodiment;

FIG. 77 is a schematic XZ cross-sectional view illustrating a configuration of a part of the semiconductor memory device according to the fifth embodiment;

FIG. 78 is a schematic XZ cross-sectional view illustrating a configuration of a part of the semiconductor memory device according to the fifth embodiment;

FIG. 79 is a schematic cross-sectional view for describing a method of manufacturing the semiconductor memory device according to the fifth embodiment;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic cross-sectional view for describing the manufacturing method;

FIG. 84 is a schematic cross-sectional view for describing the manufacturing method;

FIG. 85 is a schematic cross-sectional view for describing the manufacturing method;

FIG. 86 is a schematic cross-sectional view for describing the manufacturing method;

FIG. 87 is a schematic cross-sectional view for describing the manufacturing method;

FIG. 88 is a schematic cross-sectional view for describing the manufacturing method;

FIG. 89 is a schematic cross-sectional view for describing the manufacturing method;

FIG. 90 is a schematic cross-sectional view for describing the manufacturing method;

FIG. 91 is a schematic XY cross-sectional view illustrating a configuration of a part of a semiconductor memory device according to a sixth embodiment;

FIG. 92 is a schematic XY cross-sectional view illustrating a configuration of a part of a semiconductor memory device according to a seventh embodiment;

FIG. 93 is a schematic XZ cross-sectional view illustrating a configuration of a part of the semiconductor memory device according to the seventh embodiment;

FIG. 94 is a schematic XY cross-sectional view illustrating a configuration of a part of a semiconductor memory device according to an eighth embodiment;

FIG. 95 is a schematic XZ cross-sectional view illustrating a configuration of a part of the semiconductor memory device according to the eighth embodiment;

FIG. 96 is a schematic circuit diagram illustrating a configuration of a part of a semiconductor memory device according to a ninth embodiment;

FIG. 97 is a schematic XY cross-sectional view illustrating a configuration of a part of the semiconductor memory device according to the ninth embodiment; and

FIG. 98 is a schematic cross-sectional view illustrating a configuration of a part of the semiconductor memory device.

### DETAILED DESCRIPTION

A semiconductor memory device according to one embodiment comprises: a plurality of semiconductor layers stacked in a first direction and arranged in a second direction intersecting with the first direction and a third direction intersecting with the first direction and the second direction; a plurality of via-wirings arranged in the second direction and the third direction, extending in the first direction, and each electrically connected to the plurality of semiconductor layers stacked in the first direction; a plurality of memory portions stacked in the first direction, arranged in the second direction and the third direction, and electrically connected to the respective plurality of semiconductor layers; a plurality of gate electrodes stacked in the first direction, arranged in the second direction and the third direction, and opposed to the respective plurality of semiconductor layers; and a plurality of wiring members stacked in the first direction, arranged in the second direction and the third direction, and each disposed between two gate electrodes adjacent in the third direction among the plurality of gate electrodes. The plurality of gate electrodes include a plurality of first gate electrodes disposed at a first position in the first direction and arranged in the third direction. The plurality of wiring members include a plurality of first wiring members disposed at the first position in the first direction and arranged in the third direction. The plurality of first wiring members are mutually electrically connected via the plurality of first gate electrodes.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction. A direction along this plane and intersecting with the first direction may be referred to as a second direction, and a direction along this plane and intersecting with the second direction may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion of this configuration on the substrate side. An upper surface and an upper end of a certain configuration mean a surface and an end portion on a side opposite to the substrate of this configuration. A surface intersecting with the X-direction or the Y-direction is referred to as a side surface and the like.

In this specification, a “center position” of a certain configuration may mean, for example, a position of the center of a circumscribed circle of this configuration, and may mean the centroid on an image of this configuration.

### First Embodiment

### Circuit Configuration

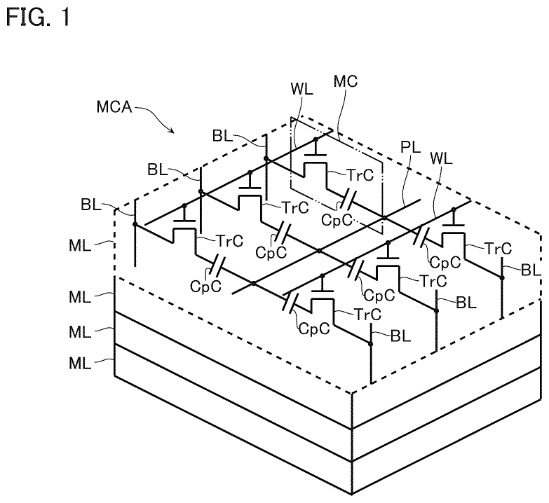

FIG. 1 is a schematic circuit diagram illustrating a configuration of a semiconductor memory device according to a first embodiment. As illustrated in FIG. 1, the semiconductor memory device according to the embodiment includes a memory cell array MCA. The memory cell array MCA includes a plurality of memory layers ML, a plurality of bit lines BL connected to these plurality of memory layers ML, and a plate line PL connected to the plurality of memory layers ML.

Each of the memory layers ML includes a plurality of word lines WL and a plurality of memory cells MC connected to these plurality of word lines WL. Each of the memory cells MC includes a transistor TrC and a capacitor CpC. The transistor TrC has one electrode connected to the bit line BL. The transistor TrC has the other electrode connected to the capacitor CpC. The one and the other electrodes of the transistor TrC function as a source electrode or a drain electrode corresponding to a voltage applied to the transistor TrC. The transistor TrC has a gate electrode connected to any of the word lines WL. The capacitor CpC has one electrode connected to the other electrode of the transistor TrC. The capacitor CpC has the other electrode connected to the plate line PL.

Each of the bit lines BL is connected to a plurality of memory cells MC corresponding to the plurality of memory layers ML.

### Structure

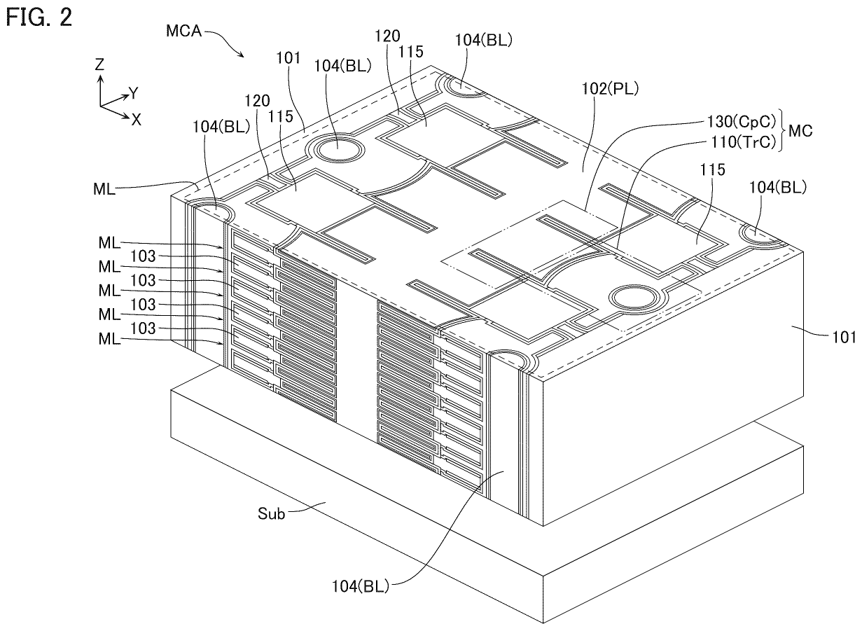

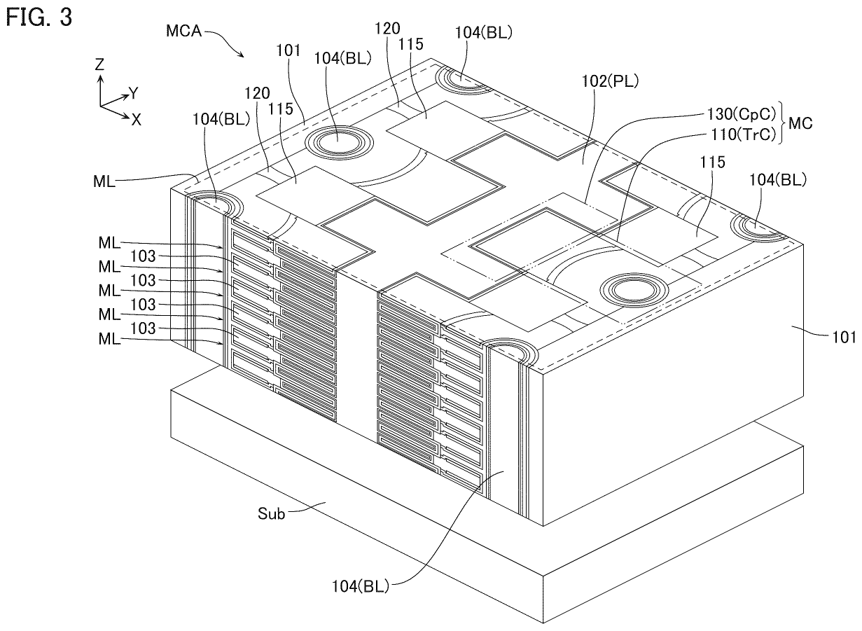

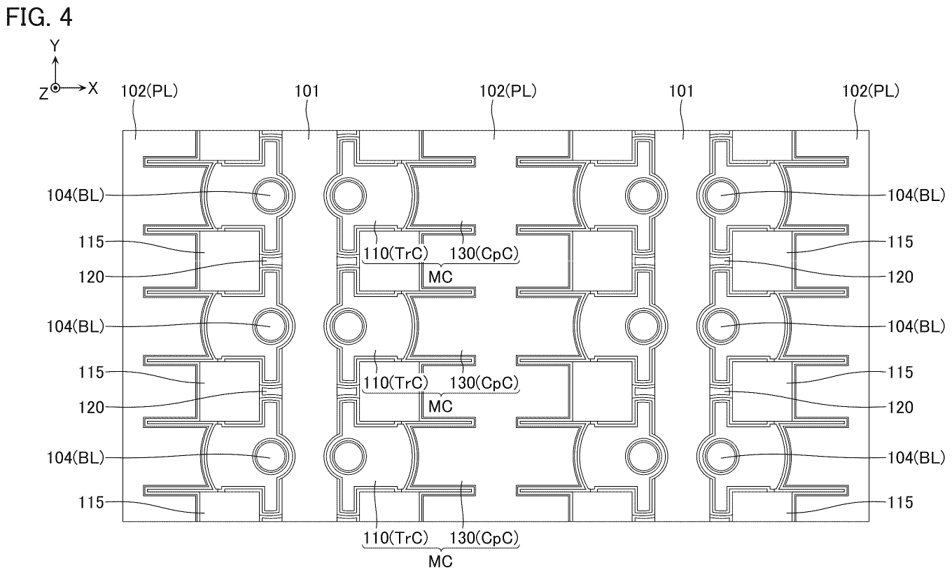

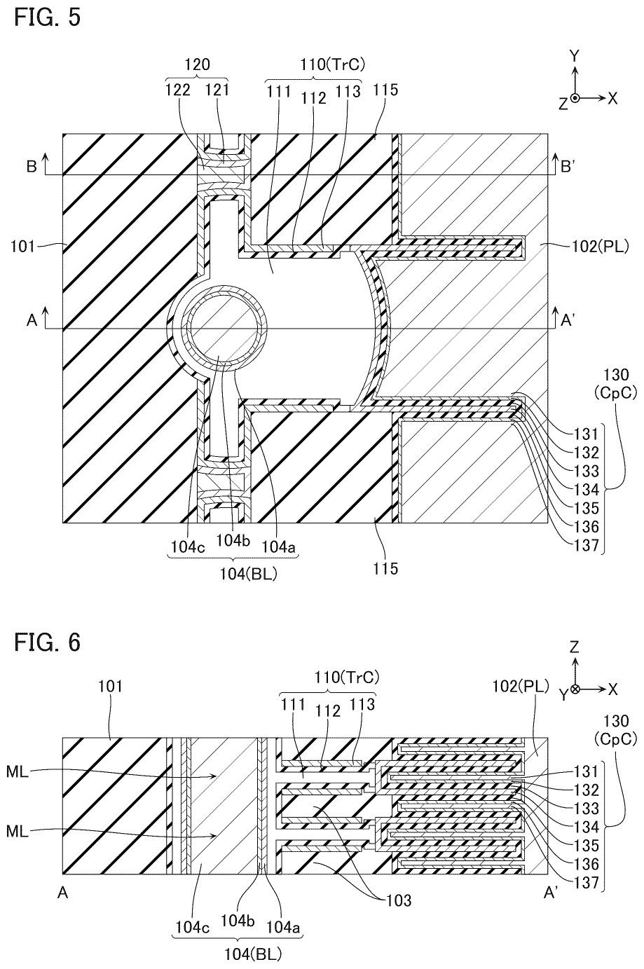

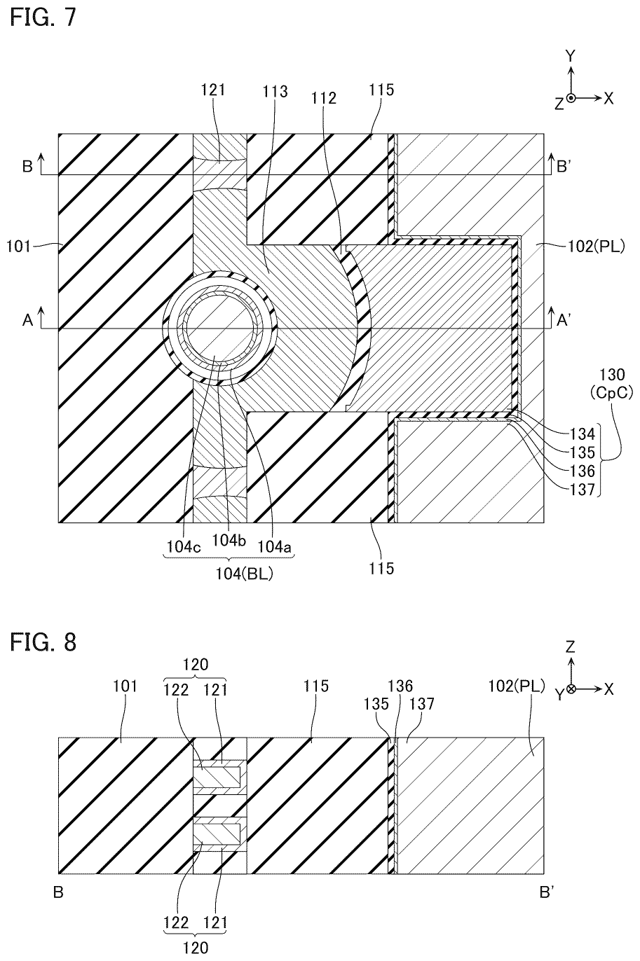

FIG. 2 and FIG. 3 are schematic perspective views illustrating configurations of a part of the semiconductor memory device according to the embodiment. FIG. 4 is a schematic XY cross-sectional view illustrating a configuration of a part of the memory layer ML. FIG. 5 is a schematic XY cross-sectional view illustrating a configuration of a part of the memory layer ML. FIG. 6 is a schematic XZ cross-sectional view illustrating a configuration of a part of the memory layer ML. FIG. 7 is a schematic XY cross-sectional view illustrating a configuration of a part of the memory layer ML. FIG. 8 is a schematic XZ cross-sectional view illustrating a configuration of a part of the memory layer ML. FIG. 5 illustrates an enlarged part of FIG. 4. FIG. 6 illustrates a cross-sectional surface of the structure illustrated in FIG. 5 and FIG. 7 taken along the line A-A′ when viewed in an arrow direction. FIG. 7 illustrates an XY cross-sectional surface corresponding to a height position different from that of FIG. 5. For example, FIG. 7 illustrates upper surfaces of a conductive layer 113 described later, a barrier conductive film 121 described later, and a conductive layer 134 described later. FIG. 8 illustrates a cross-sectional surface of the structure illustrated in FIG. 5 and FIG. 7 taken along the line B-B′ when viewed in an arrow direction.

FIG. 2 and FIG. 3 illustrate a part of a semiconductor substrate Sub, and the memory cell array MCA disposed above the semiconductor substrate Sub.

The semiconductor substrate Sub is, for example, a semiconductor substrate of silicon (Si) or the like containing P-type impurities, such as boron (B). On an upper surface of the semiconductor substrate Sub, an insulating layer and an electrode layer (not illustrated in FIG. 2 and FIG. 3) are disposed. The upper surface of the semiconductor substrate Sub and the insulating layer and electrode layer (not illustrated in FIG. 2 and FIG. 3) constitute a control circuit for controlling the semiconductor memory device according to the first embodiment. For example, in a region immediately below the memory cell array MCA, a sense amplifier circuit is disposed. The sense amplifier circuit is electrically connected to the bit lines BL. The sense amplifier circuit can read data stored in a selected memory cell MC by detecting a voltage variation or a current of the bit line BL in a read operation.

For example, as illustrated in FIG. 2 and FIG. 3, the memory cell array MCA includes a plurality of memory layers ML stacked in the Z-direction. Between the plurality of memory layers ML, respective insulating layers 103 of silicon oxide (SiO₂) or the like are disposed.

For example, as illustrated in FIG. 4, the memory cell array MCA includes a plurality of insulating layers 101 and a plurality of conductive layers 102 alternately arranged in the X-direction. For example, as illustrated in FIG. 2 and FIG. 3, the insulating layer 101 and the conductive layer 102 extend in the Y-direction and the Z-direction to separate the plurality of memory layers ML in the X-direction.

The insulating layer 101 contains, for example, silicon oxide (SiO₂).

The conductive layer 102 can include, for example, a stacked structure of titanium nitride (TiN) and tungsten (W). The conductive layer 102 may contain, for example, a conductive oxide. The conductive layer 102 may contain ruthenium (Ru), iridium (Ir), or another metal instead of the conductive oxide. The conductive layer 102 may contain only the conductive oxide, or may contain only ruthenium (Ru), iridium (Ir), or another metal. The conductive layer 102 functions as, for example, a plate line PL (FIG. 1).

In this specification, the “conductive oxide” includes, for example, indium tin oxide (ITO), indium zinc oxide (IZO), ruthenium oxide (RuO₂), iridium oxide (IrO₂), or another conductive material containing oxygen.

In each of regions between the insulating layers 101 and the conductive layers 102, a plurality of via-wirings 104 arranged in the Y-direction are disposed. For example, as illustrated in FIG. 2 and FIG. 3, the plurality of via-wirings 104 penetrate the plurality of memory layers ML and extend in the Z-direction.

As illustrated in FIG. 5 and FIG. 6, the via-wiring 104 includes, for example, a conductive oxide film 104a containing a conductive oxide, a barrier conductive film 104b of titanium nitride (TiN) or the like, and a conductive member 104c of tungsten (W) or the like. The via-wiring 104 may contain ruthenium (Ru), iridium (Ir), or another metal instead of the conductive oxide film 104a. The via-wiring 104 may contain only the conductive oxide, or may contain only ruthenium (Ru), iridium (Ir), or another metal.

The conductive member 104c has an approximately columnar shape extending in the Z-direction. The barrier conductive film 104b has an approximately cylindrical shape extending in the Z-direction along an outer peripheral surface of the conductive member 104c. The conductive oxide film 104a has an approximately cylindrical shape extending in the Z-direction along an outer peripheral surface of the barrier conductive film 104b.

For example, the via-wiring 104 functions as a bit line BL (FIG. 1). For example, as illustrated in FIG. 1, a plurality of the bit lines BL are disposed corresponding to a plurality of the transistors TrC included in the memory layer ML.

For example, as illustrated in FIG. 4, the memory layer ML includes a plurality of transistor structures 110 disposed at positions corresponding to the plurality of via-wirings 104, a plurality of wiring members 120 each disposed between two transistor structures 110 adjacent in the Y-direction and each connected to these two transistor structures 110, and a plurality of capacitor structures 130 disposed between the plurality of transistor structures 110 and the conductive layers 102.

For example, as illustrated in FIG. 5 and FIG. 6, the transistor structure 110 includes a semiconductor layer 111 connected to an outer peripheral surface of the via-wiring 104 and extending in the X-direction, an insulating layer 112 disposed on an upper surface, a lower surface, both side surfaces in the Y-direction, and a side surface on one side (insulating layer 101 side) in the X-direction, of the semiconductor layer 111, and a conductive layer 113 disposed on an upper surface, a lower surface, both side surfaces in the Y-direction, and a side surface on the one side (insulating layer 101 side) in the X-direction, of the insulating layer 112.

Each of the semiconductor layer 111 and the insulating layer 112 is disposed over a region between two insulating layers 115 described later adjacent in the Y-direction, a pair of regions between the insulating layers 115 and the insulating layer 101, and a region between the pair of regions along a circle having a center position of the via-wiring 104 as the center. The conductive layer 113 is disposed over the region between the two insulating layers 115 adjacent in the Y-direction and the pair of regions between the insulating layers 115 and the insulating layer 101. As illustrated in FIG. 7, in this embodiment, the conductive layer 113 is not disposed in the region along the circle.

In the XY cross-sectional surface as illustrated in FIG. 5, a side surface of the semiconductor layer 111 on one side (conductive layer 102 side) in the X-direction may be formed along a circle having the center position of the via-wiring 104 as the center in the region between the two insulating layers 115 adjacent in the Y-direction. Both side surfaces of the semiconductor layer 111, the insulating layer 112, and the conductive layer 113 in the Y-direction may be linearly formed along the side surfaces of the insulating layers 115.

In the XY cross-sectional surface as illustrated in FIG. 5, both side surfaces of the conductive layer 113 in the X-direction may be in contact with respective side surfaces in the X-direction of the insulating layer 115 and the insulating layer 101 in the pair of regions between the insulating layer 115 and the insulating layer 101. Both side surfaces of the semiconductor layer 111, the insulating layer 112, and the conductive layer 113 in the X-direction may be each linearly formed along the side surfaces of the insulating layer 115 and the insulating layer 101 in the X-direction. Both end portions of the semiconductor layer 111, the insulating layer 112, and the conductive layer 113 in the Y-direction may be formed along the circle having the center position of the via-wiring 104 as the center.

In this embodiment, side surfaces of the conductive layer 113 and the wiring member 120 on one side (insulating layer 101 side) in the X-direction are disposed on the other side (conductive layer 102 side) in the X-direction with respect to an end portion of the via-wiring 104 on one side (insulating layer 101 side) in the X-direction. A side surface of the wiring member 120 on the other side (conductive layer 102 side) in the X-direction is disposed on the one side (insulating layer 101 side) in the X-direction with respect to an end portion of the via-wiring 104 on the other side (conductive layer 102 side) in the X-direction. That is, in this embodiment, the wiring member 120 is disposed at a position entirely overlapping with the via-wiring 104 when viewed in the Y-direction.

In the XY cross-sectional surface as illustrated in FIG. 5, side surfaces of the semiconductor layer 111 and the insulating layer 112 on one side (insulating layer 101 side) in the X-direction may be formed along a circle having the center position of the via-wiring 104 as the center in the region along the circle having the center position of the via-wiring 104 as the center. In the example of the drawing, this side surface of the insulating layer 112 formed along the circle at one side (insulating layer 101 side) in the X-direction is not covered with the conductive layer 113, but in contact with the insulating layer 101.

The semiconductor layer 111 functions as, for example, a channel region of the transistor TrC (FIG. 1). The semiconductor layer 111 may be, for example, a semiconductor containing at least one element of gallium (Ga) or aluminum (Al) and containing indium (In), zinc (Zn), and oxygen (O), or may be another oxide semiconductor. A plurality of the semiconductor layers 111 arranged in the Z-direction are connected to a via-wiring 104 extending in the Z-direction in common.

The insulating layer 112 functions as, for example, a gate insulating film of the transistor TrC (FIG. 1). The insulating layer 112 contains, for example, silicon oxide (SiO₂).

The conductive layer 113 functions as, for example, a gate electrode of the transistor TrC (FIG. 1) and a part of the word line WL. The conductive layer 113 contains, for example, titanium nitride (TiN) or a conductive oxide, such as indium tin oxide (ITO). A plurality of the conductive layers 113 arranged in the Y-direction are connected to the wiring members 120 extending in the Y-direction in common (see FIG. 4). The conductive layer 113 is opposed to the upper surface, the lower surface, both side surfaces in the Y-direction, and the side surface on one side (insulating layer 101 side) in the X-direction of the semiconductor layer 111 via the insulating layer 112.

An insulating layer 115 of silicon oxide (SiO₂) or the like is disposed between two semiconductor layers 111 adjacent in the Y-direction. The insulating layer 115 penetrates a plurality of memory layers ML and extends in the Z-direction.

Both side surfaces of the wiring member 120 in the Y-direction are in contact with respective side surfaces of two conductive layers 113 adjacent in the Y-direction in the Y-direction. A side surface of the wiring member 120 on one side (insulating layer 101 side) in the X-direction is in contact with the insulating layer 101, and a side surface on the other side (conductive layer 102 side) is in contact with the insulating layer 115. A plurality of the wiring members 120 arranged in the Y-direction are mutually electrically connected via a plurality of the conductive layers 113 arranged in the Y-direction. The plurality of wiring members 120 and the plurality of conductive layers 113 alternately arranged in the Y-direction function as, for example, the word line WL. The wiring member 120 includes, for example, a barrier conductive film 121 of titanium nitride (TiN) or the like and a conductive film 122 of tungsten (W) or the like. The barrier conductive film 121 is disposed on an upper surface, a lower surface, both side surfaces in the Y-direction, and a side surface on the other side (conductive layer 102 side) in the X-direction, of the conductive film 122.

For example, as illustrated in FIG. 5 and FIG. 6, the capacitor structure 130 includes a conductive layer 131, a barrier conductive layer 132, an insulating layer 133, and a conductive layer 134, which are disposed in the order on an upper surface, a lower surface, both side surfaces in the Y-direction, and a side surface on one side (the transistor structure 110 side) in the X-direction, of the conductive layer 131, and an insulating layer 135, a barrier conductive layer 136, and a conductive layer 137, which are disposed in the order on an upper surface, a lower surface, and both side surfaces in the Y-direction, of the conductive layer 134. The insulating layer 135 and the barrier conductive layer 136 are continuous with the insulating layer 133 and the barrier conductive layer 132, respectively.

The conductive layer 131, the barrier conductive layer 132, the barrier conductive layer 136, and the conductive layer 137 function as one electrode of the capacitor CpC (FIG. 1). The conductive layers 131, 137 may contain, for example, tungsten (W), ruthenium (Ru), iridium (Ir), or another metal. The barrier conductive layers 132, 136 may contain, for example, titanium nitride (TiN). The barrier conductive layers 132, 136 may be omitted. The conductive layer 131, the barrier conductive layer 132, the barrier conductive layer 136, and the conductive layer 137 are continuous with the conductive layer 102.

The insulating layers 133, 135 function as insulating layers of the capacitor CpC (FIG. 1). The insulating layers 133, 135 may be, for example, zirconia (ZrO₂), alumina (Al₂O₃), or another insulating metal oxide. The insulating layers 133, 135 may be, for example, a stacked film of a plurality of insulating metal oxides (for example, a stacked film of zirconia and alumina).

The conductive layer 134 functions as, for example, the other electrode of the capacitor CpC (FIG. 1). The conductive layer 134 contains, for example, a conductive oxide, such as indium tin oxide (ITO). The conductive layer 134 is insulated from the barrier conductive layers 132, 136 via the insulating layers 133, 135. The conductive layer 134 is connected to a side surface of the semiconductor layer 111 on one side (conductive layer 102 side) in the X-direction.

### Manufacturing Method

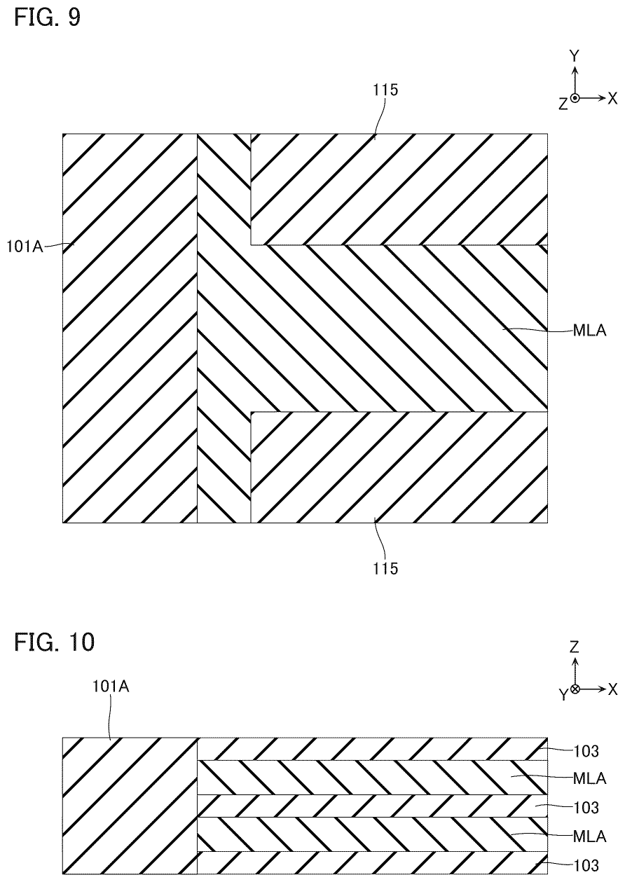

FIG. 9 to FIG. 64 are schematic cross-sectional views for describing a method of manufacturing the semiconductor memory device according to the first embodiment.

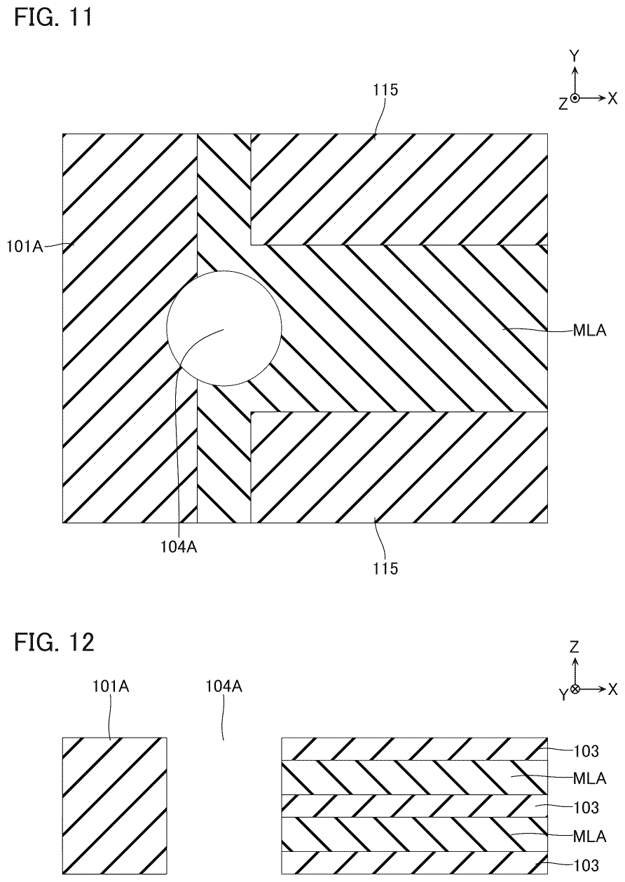

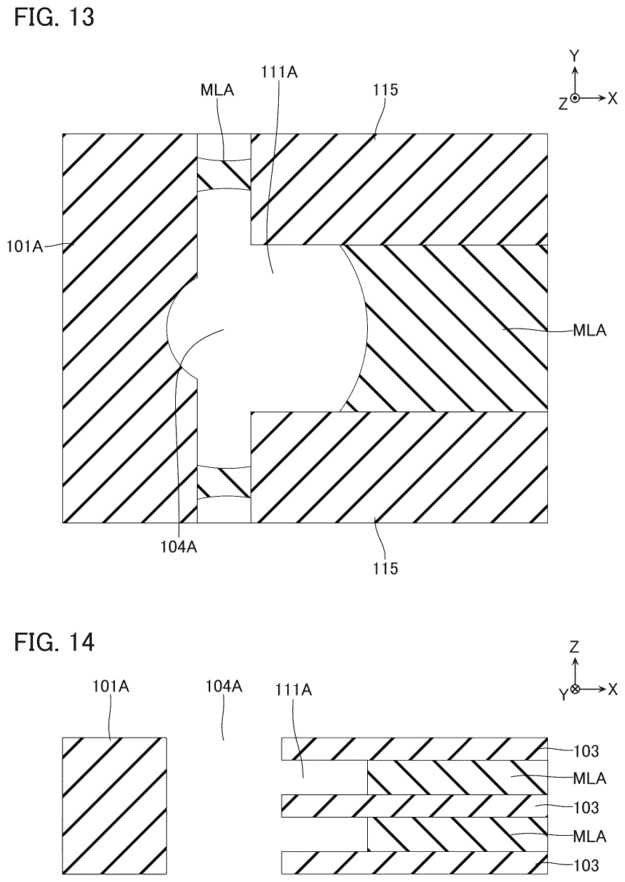

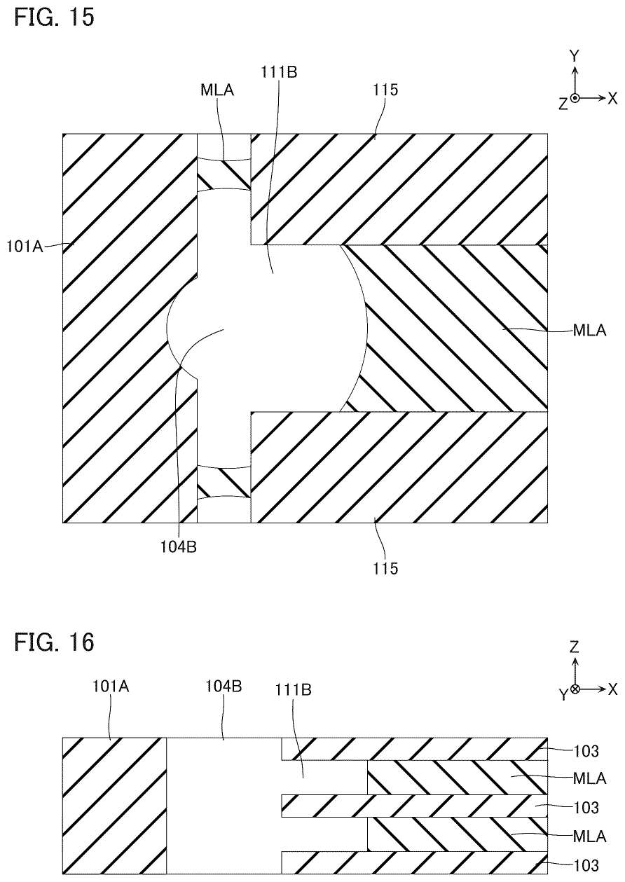

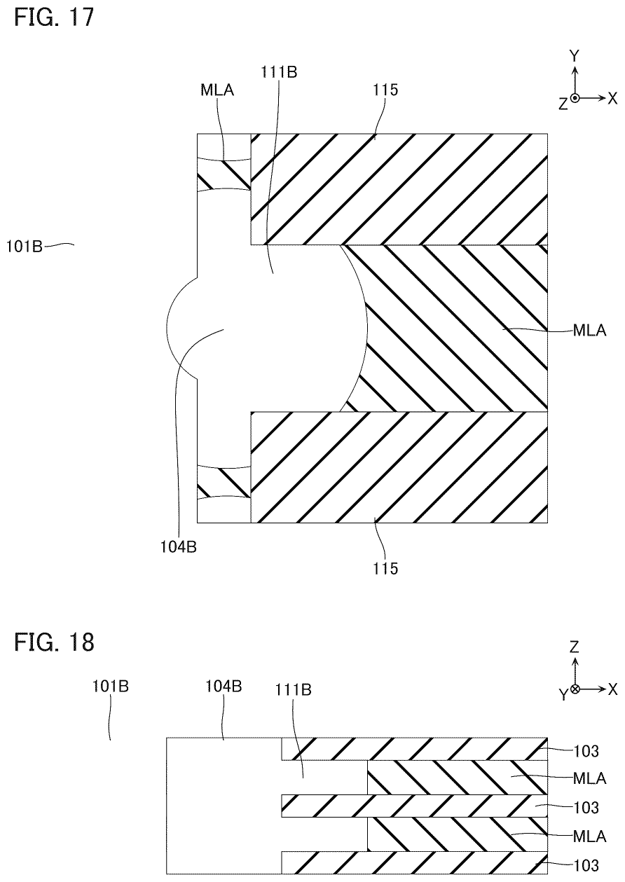

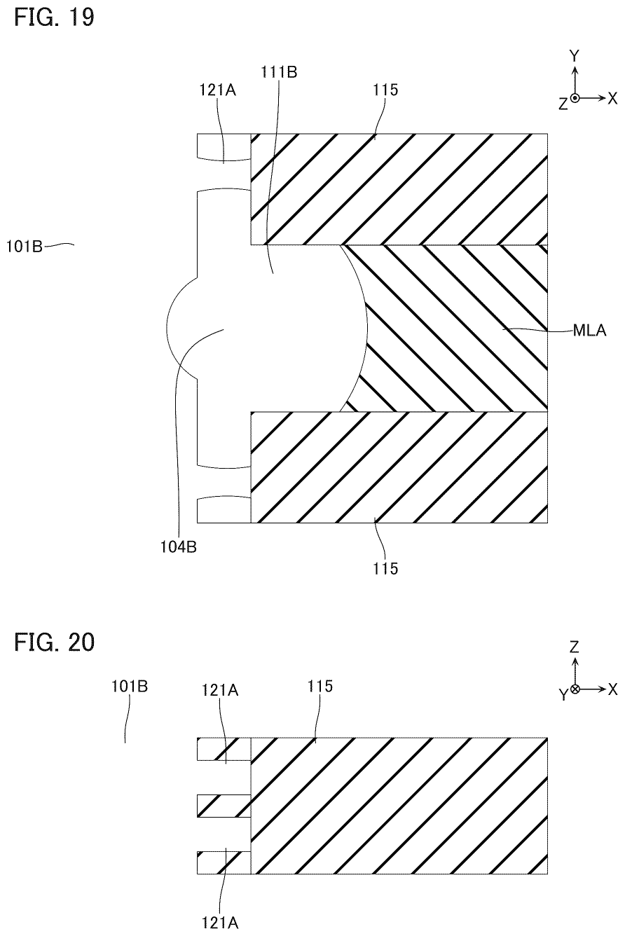

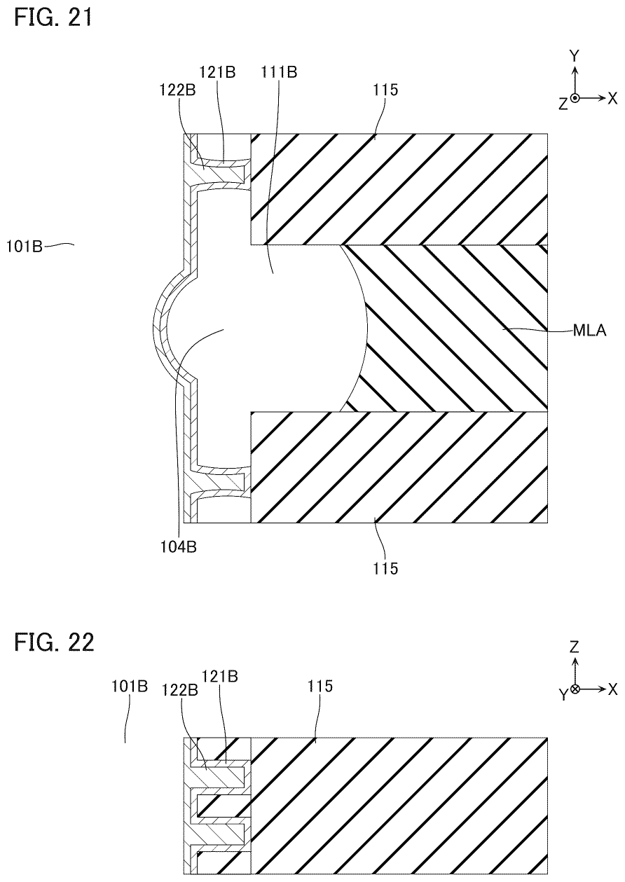

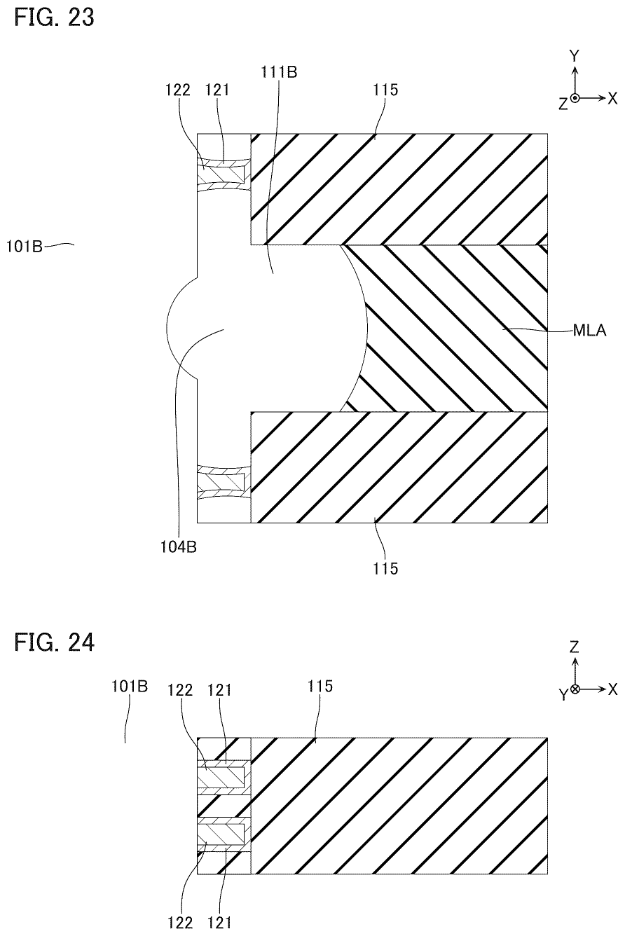

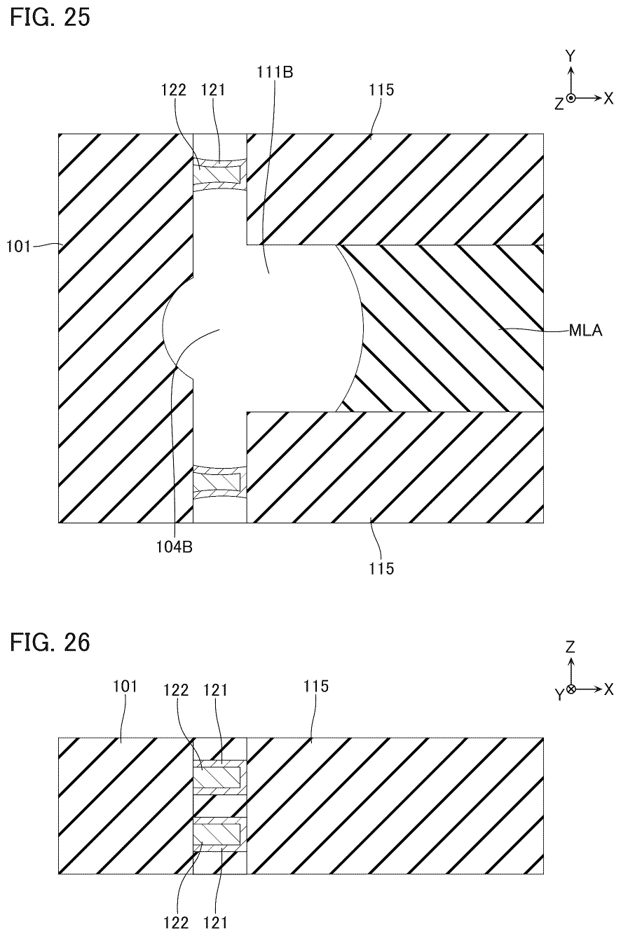

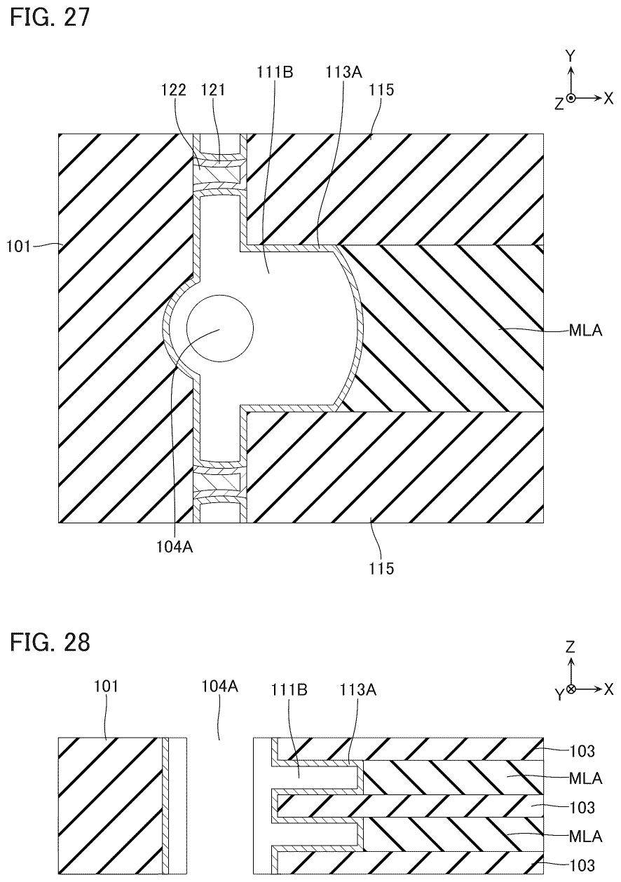

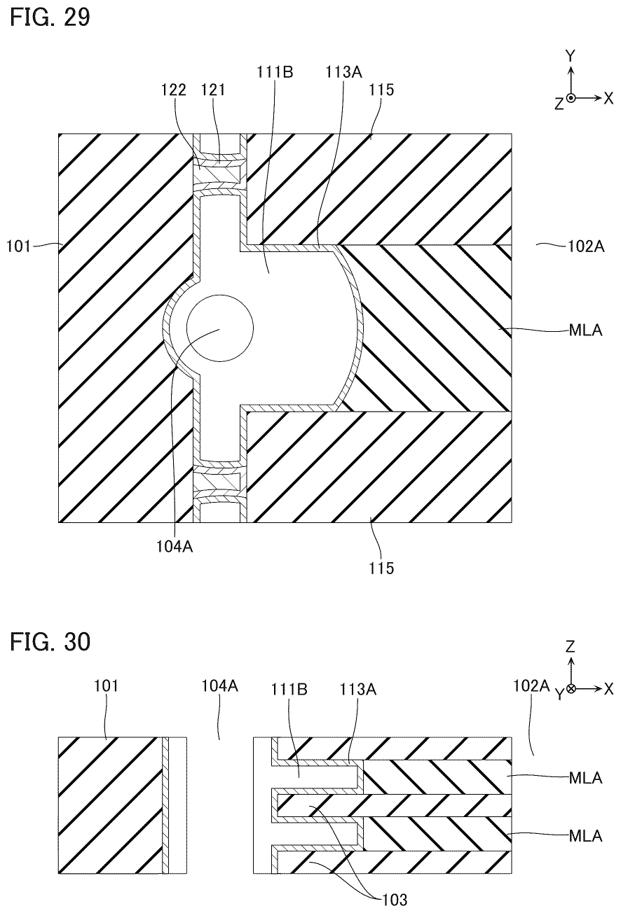

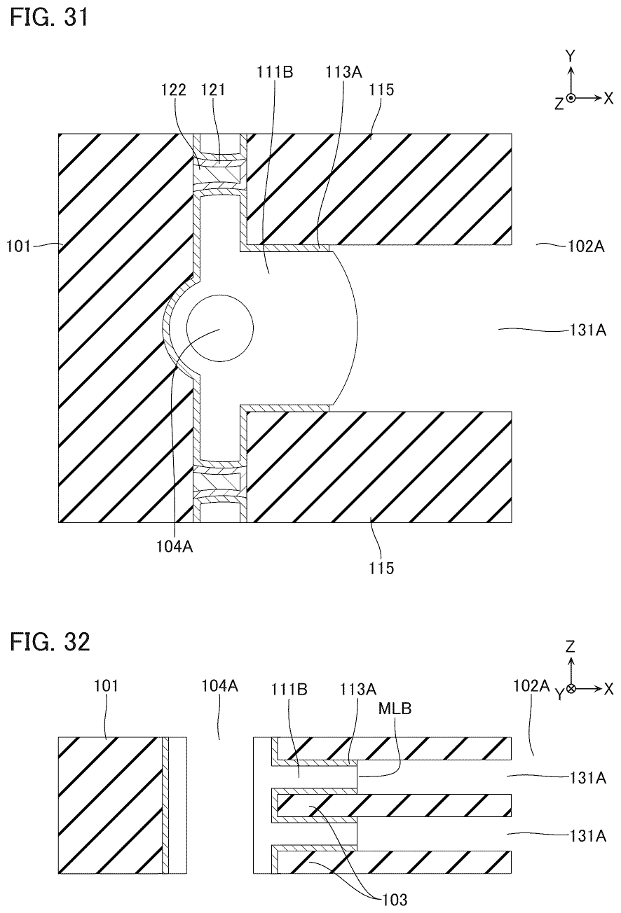

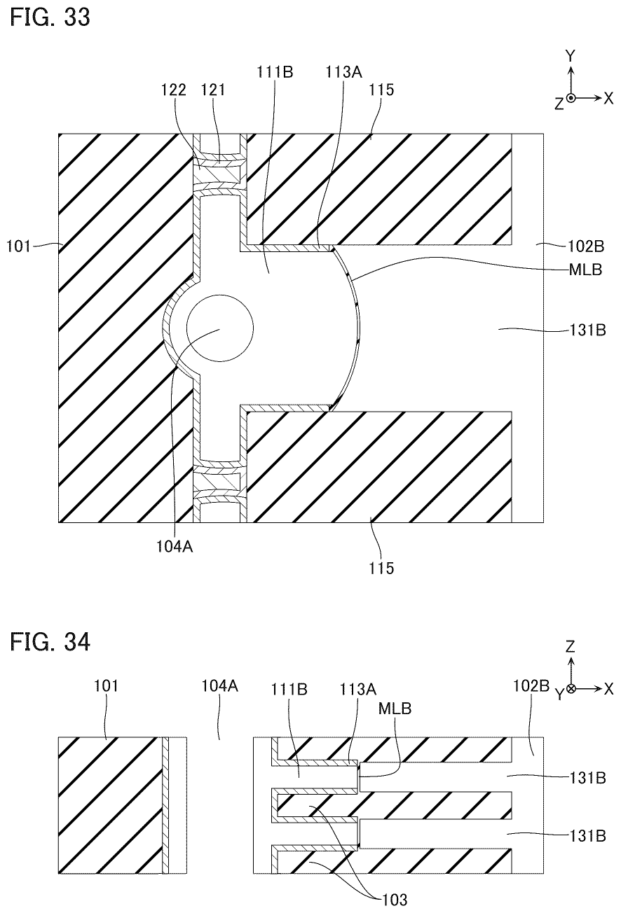

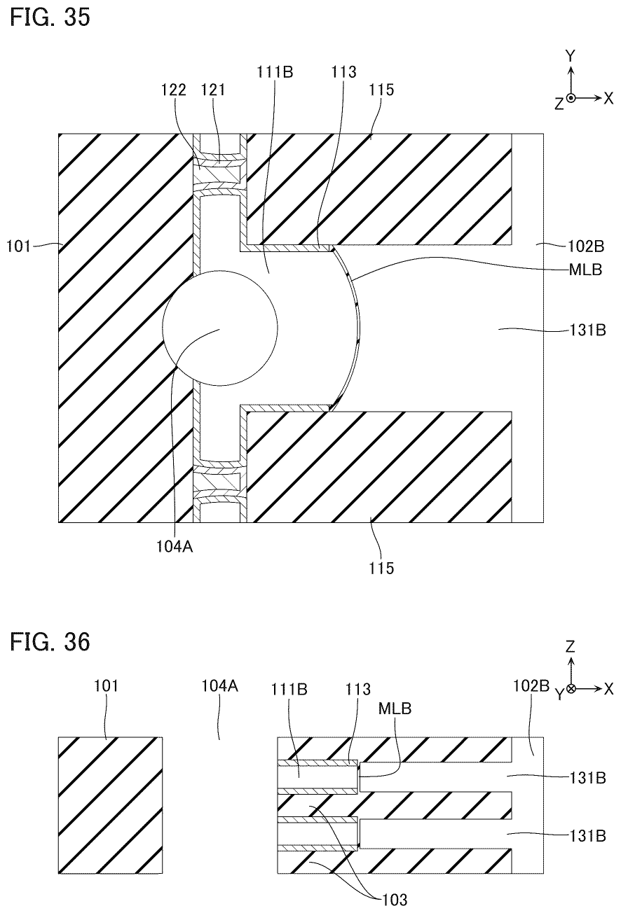

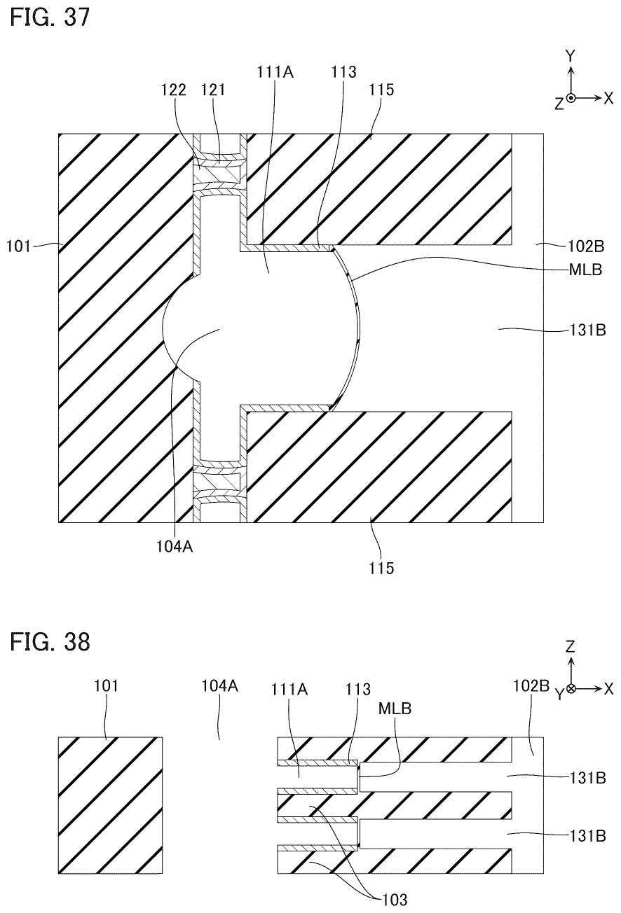

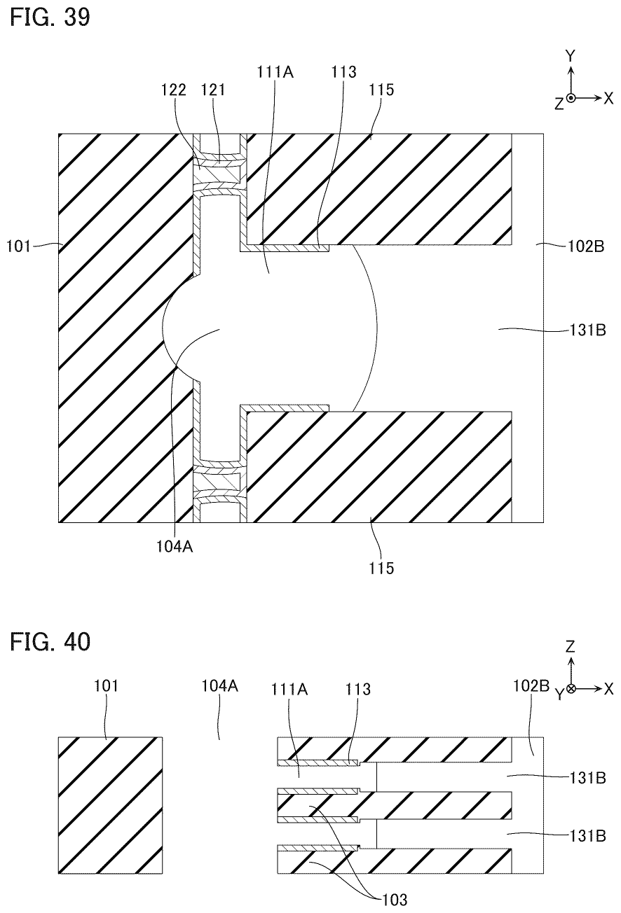

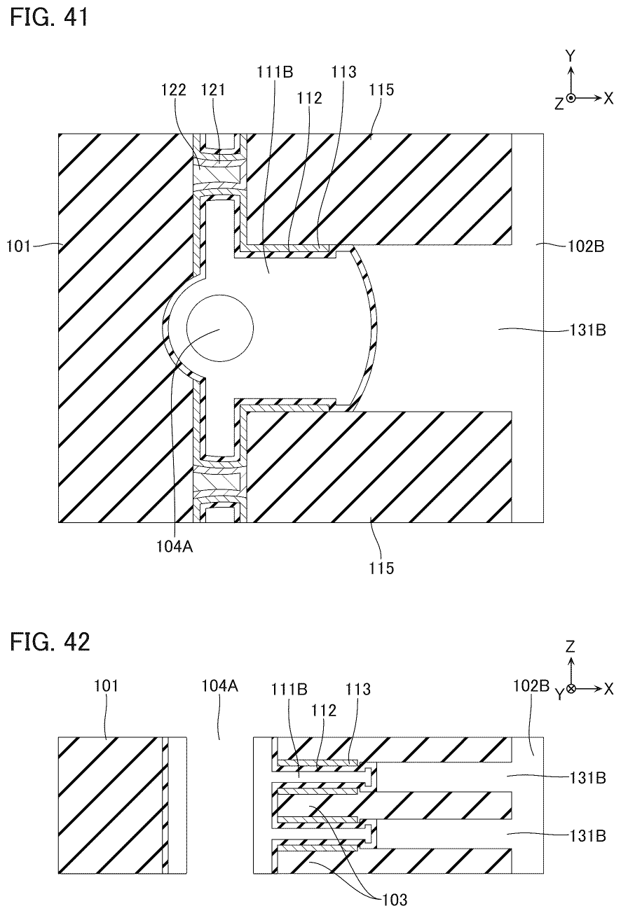

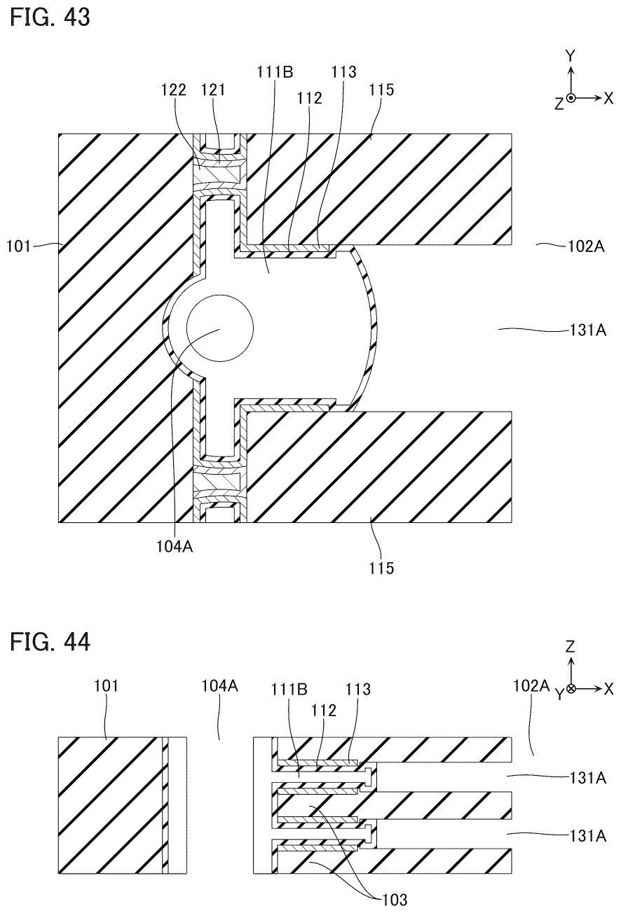

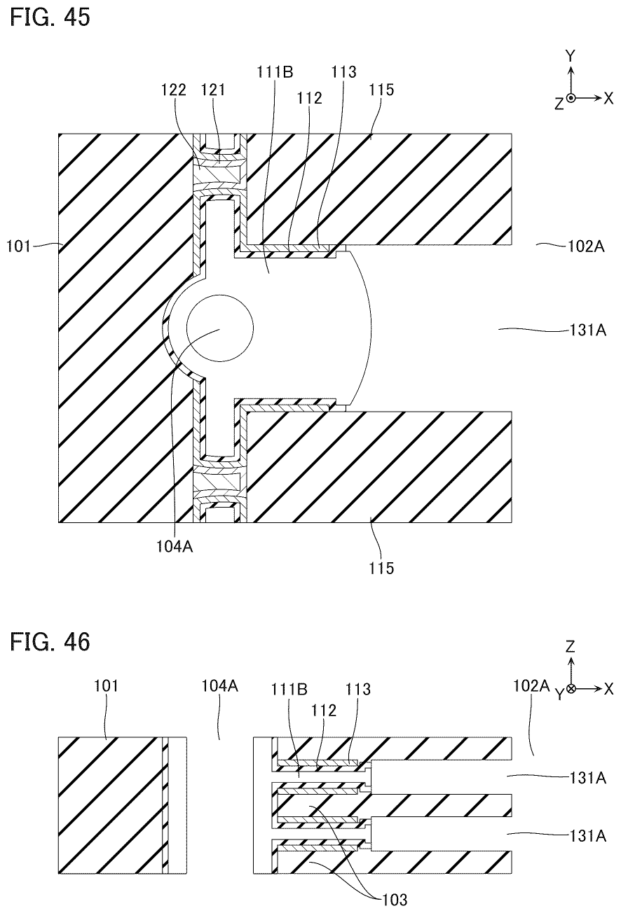

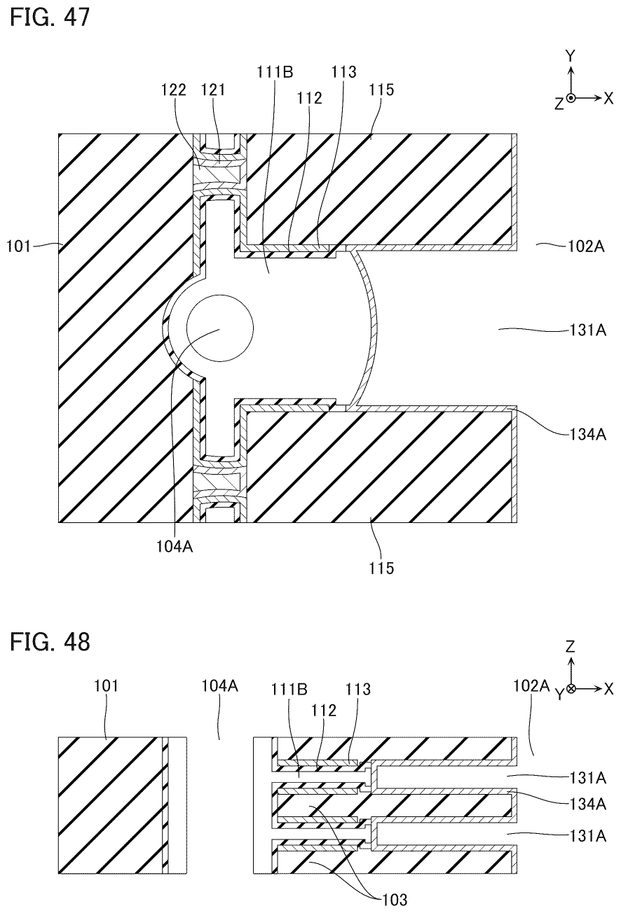

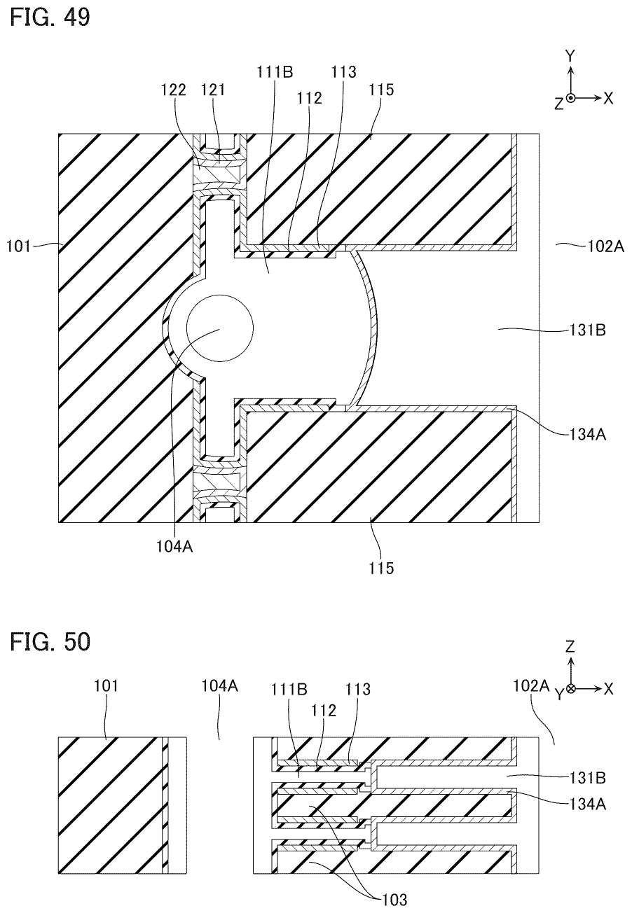

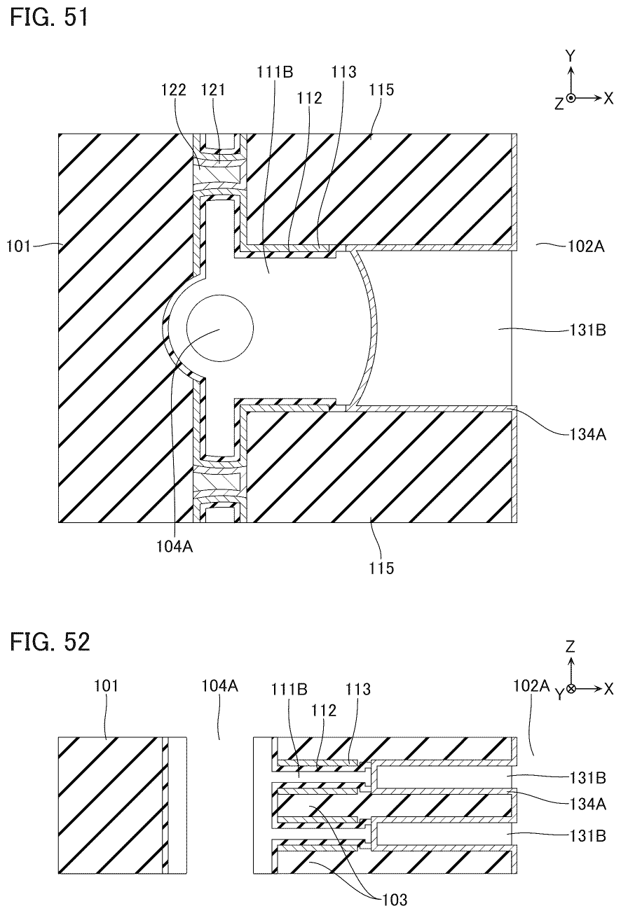

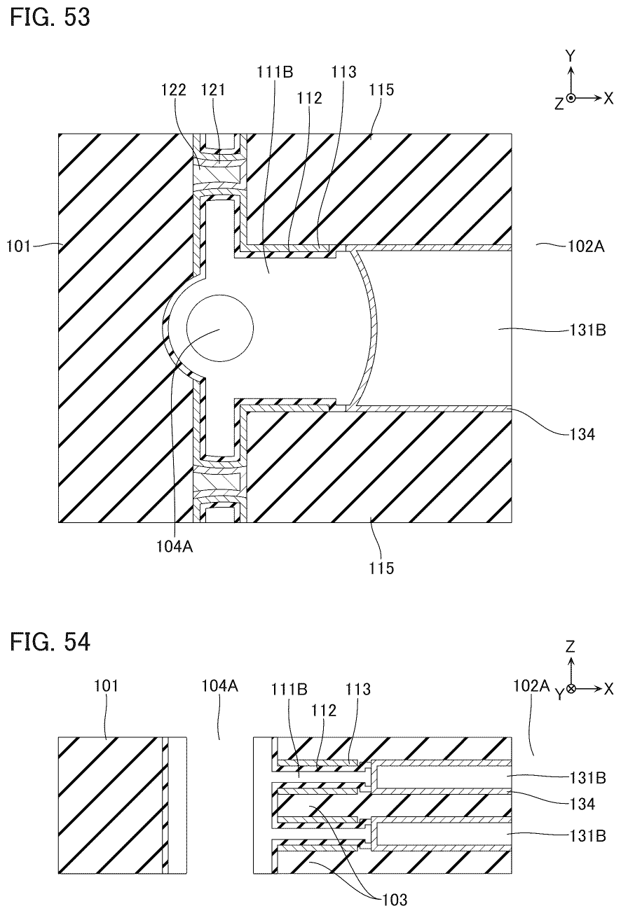

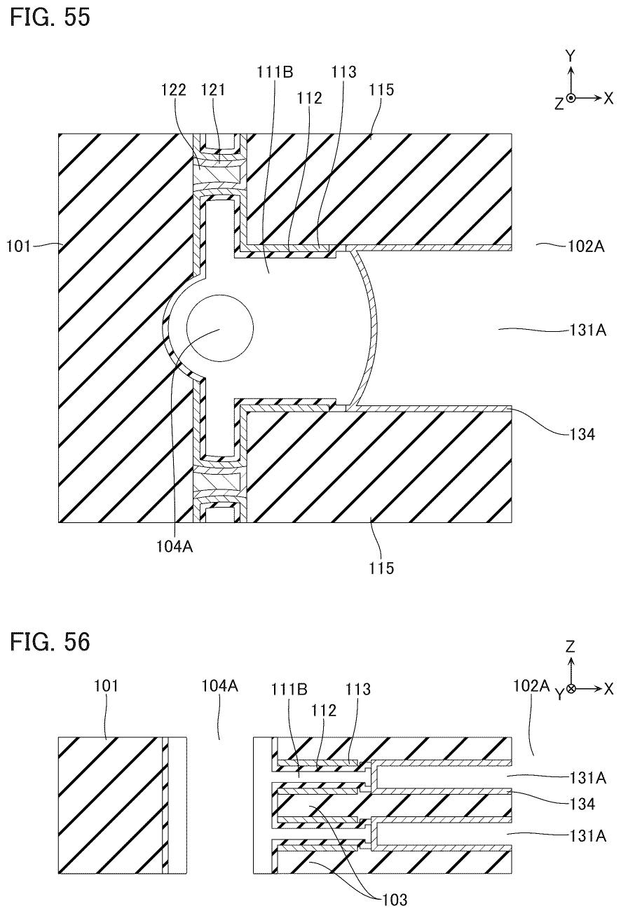

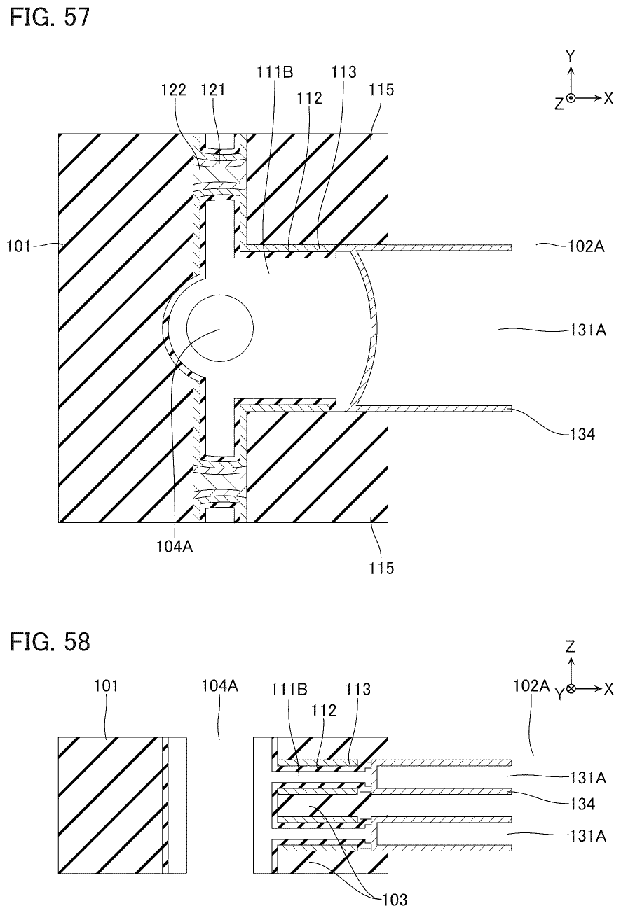

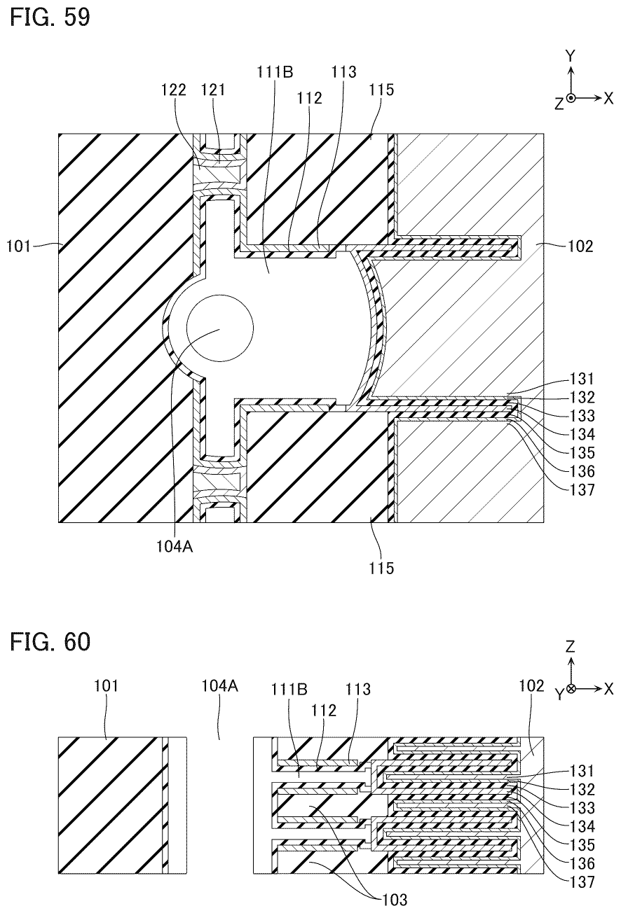

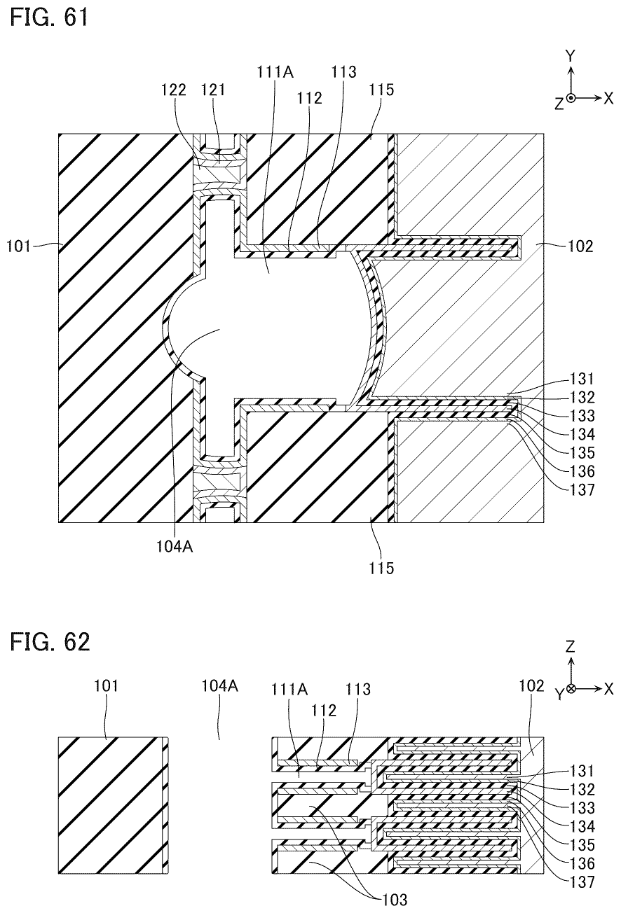

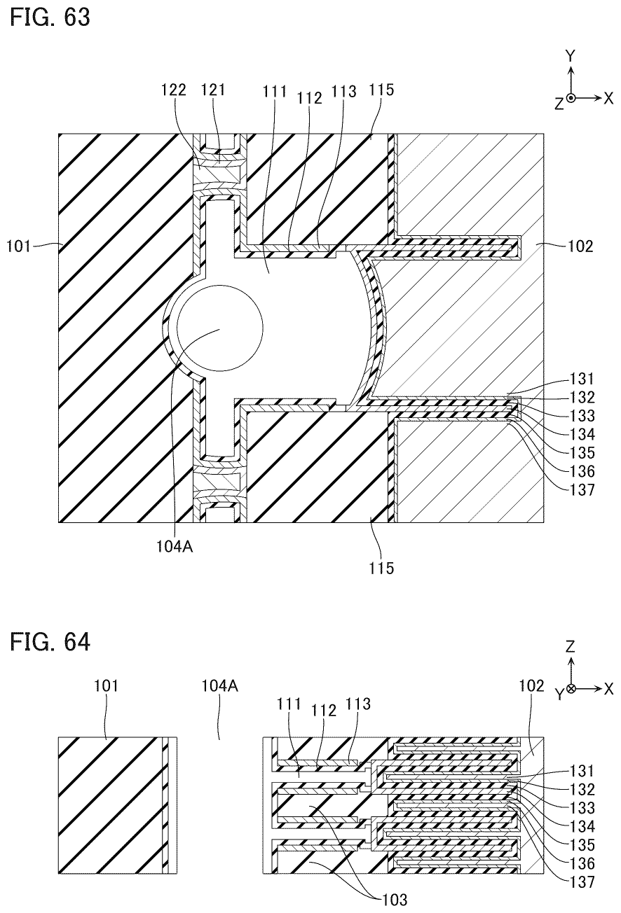

FIG. 9, FIG. 11, FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, FIG. 45, FIG. 47, FIG. 49, FIG. 51, FIG. 53, FIG. 55, FIG. 57, FIG. 59, FIG. 61, and FIG. 63 illustrate cross-sectional surfaces corresponding to FIG. 5.

FIG. 10, FIG. 12, FIG. 14, FIG. 16, FIG. 18, FIG. 28, FIG. 30, FIG. 32, FIG. 34, FIG. 36, FIG. 38, FIG. 40, FIG. 42, FIG. 44, FIG. 46, FIG. 48, FIG. 50, FIG. 52, FIG. 54, FIG. 56, FIG. 58, FIG. 60, FIG. 62, and FIG. 64 illustrate cross-sectional surfaces corresponding to FIG. 6.

FIG. 20, FIG. 22, FIG. 24, and FIG. 26 illustrate cross-sectional surfaces corresponding to FIG. 8.

In the manufacturing method, for example, as illustrated in FIG. 10, a plurality of insulating layers 103 and a plurality of sacrifice layers MLA are alternately formed. The sacrifice layer MLA contains, for example, silicon nitride (Si₃N₄). This process is performed by, for example, Chemical Vapor Deposition (CVD).

Next, for example, as illustrated in FIG. 9 and FIG. 10, a sacrifice layer 101A and the insulating layers 115 are formed. In this process, for example, openings are formed at positions corresponding to the insulating layers 101, 115. This opening extends in the Z-direction, and penetrates a plurality of insulating layers 103 and the plurality of sacrifice layers MLA stacked in the Z-direction. This process is performed by, for example, RIE. After forming the openings, the sacrifice layer 101A and the insulating layers 115 are formed. This process is performed by, for example, CVD.

Next, for example, as illustrated in FIG. 11 and FIG. 12, an opening 104A is formed at a position corresponding to the via-wiring 104. The opening 104A extends in the Z-direction, and penetrates the plurality of insulating layers 103 and the plurality of sacrifice layers MLA stacked in the Z-direction and the sacrifice layer 101A. This process is performed by, for example, RIE.

Next, for example, as illustrated in FIG. 13 and FIG. 14, openings 111A are formed at positions corresponding to the transistor structures 110. A part of the opening 111A is provided in a region between two insulating layers 115 adjacent in the Y-direction. In this region, a part of an upper surface of the insulating layer 103, a part of a lower surface of the insulating layer 103, parts of a side surface of the sacrifice layer MLA in the X-direction, and parts of side surfaces of the insulating layers 115 in the Y-direction are exposed to an inside of the opening 111A. Other parts of the opening 111A are provided in regions between the insulating layers 115 and the sacrifice layer 101A. In these regions, a part of the upper surface of the insulating layer 103, a part of the lower surface of the insulating layer 103, a part of a side surface of the sacrifice layer MLA in the Y-direction, a part of a side surface of the insulating layer 115 in the X-direction, and a part of a side surface of the sacrifice layer 101A in the X-direction are exposed to the inside of the opening 111A, respectively. In this process, to avoid communication between two openings 104A adjacent in the Y-direction via the opening 111A, the sacrifice layer MLA is left between two openings 111A adjacent in the Y-direction. In this process, for example, parts of the sacrifice layers MLA are selectively removed via the opening 104A. This process is performed by, for example, wet etching.

Next, for example, as illustrated in FIG. 15 and FIG. 16, sacrifice layers 104B, 111B of silicon (Si) or the like are filled in the openings 104A, 111A. This process is performed by, for example, CVD.

Next, for example, as illustrated in FIG. 17 and FIG. 18, the sacrifice layer 101A is removed to form an opening 101B. This process is performed by, for example, wet etching.

Next, for example, as illustrated in FIG. 19 and FIG. 20, openings 121A are formed at positions corresponding to the wiring members 120. A part of the upper surface of the insulating layer 103, a part of the lower surface of the insulating layer 103, side surfaces in the Y-direction of the sacrifice layers 111B, and a part of the side surface of the insulating layer 115 in the X-direction are exposed to an inside of the opening 121A. In this process, for example, parts of the sacrifice layers MLA are removed via the opening 101B. This process is performed by, for example, wet etching.

Next, for example, as illustrated in FIG. 21 and FIG. 22, a barrier conductive film 121B and a conductive film 122B are formed on parts of the upper surfaces, parts of the lower surfaces, and side surfaces in the X-direction (exposed surfaces of the insulating layer 103 to the openings 101B, 121A), of the insulating layer 103, both side surfaces in the Y-direction and side surfaces on one side in the X-direction (exposed surfaces of the sacrifice layer 111B to the openings 101B, 121A), of the sacrifice layers 111B, and parts of side surfaces of the insulating layers 115 in the X-direction (exposed surface of the insulating layer 115 to the opening 121A). In this process, the opening 121A is filled with the conductive film 122B. On the other hand, the opening 101B is not filled with the conductive film 122B. This process is performed by, for example, CVD.

Next, for example, as illustrated in FIG. 23 and FIG. 24, the wiring members 120 are formed. For example, in the barrier conductive film 121B and the conductive film 122B, parts formed inside the openings 121A are left, a part formed inside the opening 101B is selectively removed to expose the side surfaces of the insulating layers 103 in the X-direction and the side surfaces of the sacrifice layers 111B on one side in the X-direction, thereby separating the barrier conductive film 121B and the conductive film 122B in the Y-direction and the Z-direction. This process is performed by, for example, wet etching.

For example, as illustrated in FIG. 25 and FIG. 26, the insulating layer 101 is formed inside the opening 101B. This process is performed by, for example, CVD.

Next, the sacrifice layers 104B, 111B are removed. This process is performed by, for example, wet etching.

Next, for example, as illustrated in FIG. 27 and FIG. 28, a conductive layer 113A and a sacrifice layer 111B are formed on parts of the upper surfaces and parts of the lower surfaces (exposed surfaces of the insulating layers 103 to the opening 111A), and parts of the side surfaces (exposed surfaces of the insulating layers 103 to the opening 104A) of the insulating layer 103, the side surfaces in the X-direction, of the sacrifice layers MLA (exposed surfaces of the sacrifice layers MLA to the openings 111A), parts of the side surfaces of the insulating layers 115 in the X-direction and the Y-direction (exposed surfaces of the insulating layers 115 to the openings 111A), the side surfaces of the barrier conductive films 121B in the Y-direction, and a part of the side surface of the insulating layer 101 in the X-direction (exposed surface of the insulating layer 101 to the opening 111A). In this process, the openings 111A are filled with the sacrifice layer 111B. On the other hand, the opening 104A is not filled with the sacrifice layer 111B. This process is performed by, for example, CVD.

Next, an insulating layer or the like (not illustrated in FIG. 27 and FIG. 28) is formed above the opening 104A to close the opening 104A.

Next, for example, as illustrated in FIG. 29 and FIG. 30, an opening 102A is formed at a position corresponding to the conductive layer 102. The opening 102A extends in the Y-direction and the Z-direction, and penetrates the plurality of insulating layers 103 and the plurality of sacrifice layers MLA stacked in the Z-direction and the plurality of insulating layers 115, thereby separating these configurations in the X-direction. This process is performed by, for example, RIE.

Next, for example, as illustrated in FIG. 31 and FIG. 32, openings 131A are formed at positions corresponding to the capacitor structures 130. In this process, the sacrifice layers MLA are removed via the opening 102A to expose the side surfaces of the conductive layers 113A in the X-direction. This process is performed by, for example, wet etching.

Next, parts of the conductive layers 113A are removed via the openings 131A to expose side surfaces of the sacrifice layers 111B in the X-direction. This process is performed by, for example, wet etching.

Next, for example, as illustrated in FIG. 33 and FIG. 34, an oxide film MLB is formed on the side surfaces of the sacrifice layers 111B in the X-direction. This process is performed by, for example, an oxidation process. Further, the openings 131A, 102A are filled with sacrifice layers 131B, 102B of silicon (Si) or the like. This process is performed by, for example, CVD.

Next, for example, as illustrated in FIG. 35 and FIG. 36, the conductive layers 113 are formed. In this process, for example, a part of the sacrifice layer 111B and parts of the conductive layer 113A are removed via the opening 104A to expose the insulating layer 103 and the insulating layer 101, thereby separating the conductive layer 113A in the Z-direction. This process is performed by, for example, wet etching.

Next, for example, as illustrated in FIG. 37 and FIG. 38, the sacrifice layer 111B is removed. This process is performed by, for example, wet etching.

Next, for example, as illustrated in FIG. 39 and FIG. 40, the oxide film MLB is removed. This process is performed by, for example, wet etching. Further, a part of the sacrifice layer 131B is removed. This process is performed by, for example, wet etching.

Next, for example, as illustrated in FIG. 41 and FIG. 42, the insulating layer 112 and a sacrifice layer 111B are formed on exposed surfaces of the conductive layers 113 to the openings 111A, parts of the upper surfaces and part of the lower surfaces of the insulating layer 103 (exposed surfaces of the insulating layers 103 to the openings 111A), parts of the side surfaces of the insulating layer 103 in the X-direction (exposed surfaces of the insulating layer 103 to the opening 104A) of the insulating layer 103, side surfaces of the sacrifice layers 131B in the X-direction (exposed surfaces of the sacrifice layers 131B to the openings 111A), parts of the side surfaces of the insulating layers 115 in the Y-direction (exposed surfaces of the insulating layers 115 to the openings 111A), and a part of the side surface of the insulating layer 101 in the X-direction (exposed surface of the insulating layer 101 to the opening 104A). In this process, the opening 111A is filled with the sacrifice layer 111B. On the other hand, the opening 104A is not filled with the sacrifice layer 111B. This process is performed by, for example, CVD.

Next, an insulating layer or the like (not illustrated FIG. 41 and FIG. 42) is formed above the opening 104A to close the opening 104A.

Next, for example, as illustrated in FIG. 43 and FIG. 44, the sacrifice layers 131B, 102B are removed. This process is performed by, for example, wet etching.

Next, for example, as illustrated in FIG. 45 and FIG. 46, parts of the insulating layer 112 are removed via the opening 131A to expose the side surfaces of the sacrifice layers 111B in the X-direction. This process is performed by, for example, wet etching.

Next, for example, as illustrated in FIG. 47 and FIG. 48, conductive layers 134A are formed on side surfaces of the sacrifice layers 111B on one side in the X-direction (exposed surface to the opening 131A), the upper surfaces and the lower surfaces (exposed surfaces to the opening 131A) of the insulating layer 103, the side surface on one side in the X-direction (exposed surface to the opening 102A) of the insulating layer 103, and parts of the side surfaces in the Y-direction (exposed surface to the openings 131A) and the side surfaces in the X-direction (exposed surfaces to the opening 102A) of the insulating layers 115 via the opening 102A and the opening 131A. This process is performed by, for example, Atomic Layer Deposition (ALD).

Next, for example, as illustrated in FIG. 49 and FIG. 50, a sacrifice layer 131B of silicon (Si) or the like is formed at the openings 131A, 102A. The openings 131A are filled with the sacrifice layer 131B. On the other hand, the opening 102A is not filled with the sacrifice layer 131B. This process is performed by, for example, CVD.

Next, for example, as illustrated in FIG. 51 and FIG. 52, in the sacrifice layer 131B, parts disposed on the side surfaces of the insulating layers 115 and the insulating layers 103 in the X-direction are removed to expose parts of the conductive layer 134A. This process is performed by, for example, wet etching.

Next, for example, as illustrated in FIG. 53 and FIG. 54, the conductive layers 134 are formed. For example, in the conductive layer 134A, parts disposed on the side surfaces of the insulating layers 115 and the insulating layers 103 in the X-direction are removed to separate the conductive layer 134A in the Y-direction and the Z-direction. This process is performed by, for example, wet etching.

Next, for example, as illustrated in FIG. 55 and FIG. 56, the sacrifice layer 131B is removed. This process is performed by, for example, wet etching.

Next, for example, as illustrated in FIG. 57 and FIG. 58, the insulating layers 103, 115 are partially removed.

This process is performed by, for example, wet etching.

Next, for example, as illustrated in FIG. 59 and FIG. 60, the capacitor structure 130 is formed. In this process, for example, the insulating layer 133, the insulating layer 135, the barrier conductive layer 132, the barrier conductive layer 136, the conductive layer 131, and the conductive layer 137 are formed on the upper surfaces, the lower surfaces, the side surfaces on one side (side surface on the opening 102A side) in the X-direction, and both side surfaces in the Y-direction, of the conductive layers 134, and the side surfaces of the insulating layer 115 and the insulating layer 103 in the X-direction via the opening 131A and the opening 102A. This process is performed by, for example, CVD.

Next, for example, as illustrated in FIG. 61 and FIG. 62, the sacrifice layer 111B is removed. This process is performed by, for example, wet etching.

Next, for example, as illustrated in FIG. 63 and FIG. 64, the semiconductor layers 111 are formed inside the openings 111A, 104A. The openings 111A are filled with the semiconductor layers 111. On the other hand, the opening 104A is not filled with the semiconductor layers 111. This process is performed by, for example, ALD.

Then, for example, as illustrated in FIG. 5 and FIG. 6, the conductive oxide film 104a, the barrier conductive film 104b, and the conductive member 104c are formed inside the opening 104A. This process is performed by a method, such as ALD, CVD, for example. Accordingly, the structure described with reference to FIG. 2 to FIG. 8 is formed.

### Effects

According to the method as described with reference to FIG. 9 to FIG. 64, only by increasing the numbers of the sacrifice layers MLA and the insulating layers 103 stacked in the process described with reference to FIG. 9 and FIG. 10, the number of the memory layers ML included in the memory cell array MCA can be increased. Accordingly, the high integration of the memory cell array MCA can be relatively easily achieved almost without the increase in manufacturing cost.

The semiconductor memory device manufactured by such a method includes a plurality of the memory layers ML arranged in the Z-direction and the via-wiring 104 extending in the Z-direction. The configurations in the plurality of memory layers ML (the transistor structure 110, the wiring member 120, the capacitor structure 130, and the like) are all different in position when viewed in the Z-direction. The configurations in the memory layer ML have a symmetrical structure in an up-down direction.

Here, in such a semiconductor memory device, for example, it is also considered to dispose a wiring extending in the Y-direction between the transistor structure 110 and the insulating layer 101 and use this wiring as the word line WL.

However, a length in the X-direction for each memory cell MC includes a length of a half of a length of the opening 101B (FIG. 23) in the X-direction, a length of a half of a length of the opening 102A (FIG. 29) in the X-direction, a length of the transistor structure 110 in the X-direction, and a length of the capacitor structure 130 in the X-direction. Here, since the openings 101B, 102A penetrate the plurality of insulating layers 103 and the plurality of sacrifice layers MLA stacked in the Z-direction and extend in the Z-direction, the openings 101B, 102A need to be relatively deep. In view of this, the lengths in the X-direction of the openings 101B, 102A tend to become large as the numbers of the sacrifice layers MLA and the insulating layers 103 stacked in the Z-direction increase, and the reduction is difficult in some cases. Further, since the lengths in the X-direction of the transistor structure 110 and the capacitor structure 130 are determined corresponding to a channel length of the transistor TrC and a capacitance of the capacitor CpC, the reduction is difficult in some cases.

Therefore, for example, as described above, when a wiring extending in the Y-direction is disposed between the transistor structure 110 and the insulating layer 101, and this wiring is used as the word line WL, the length in the X-direction for each memory cell MC becomes relatively large in some cases.

Therefore, in the semiconductor memory device according to the embodiment, a plurality of the conductive layers 113 arranged in the Y-direction are connected via a plurality of the wiring members 120, and used as the word lines WL.

This configuration eliminates the need for disposing the wiring extending the Y-direction between the transistor structure 110 and the insulating layer 101. Accordingly, the high integration of the semiconductor memory device can be attempted by decreasing the length in the X-direction for each memory cell MC.

Additionally, in such a semiconductor memory device, for example, it is also considered that the side surfaces of the conductive layer 113 and the wiring member 120 on one side (insulating layer 101 side) in the X-direction are disposed on the one side (insulating layer 101 side) in the X-direction with respect to the end portion of the via-wiring 104 on the one side (insulating layer 101 side) in the X-direction.

However, in such a configuration, since the length in the X-direction for each memory cell MC includes a length of the via-wiring 104 in the X-direction, the length in the X-direction for each memory cell MC possibly becomes large.

Therefore, in the semiconductor memory device according to the embodiment, the side surfaces of the conductive layer 113 and the wiring member 120 on the one side (insulating layer 101 side) in the X-direction are disposed on the other side (conductive layer 102 side) in the X-direction with respect to the end portion of the via-wiring 104 on the one side (insulating layer 101 side) in the X-direction.

With this configuration, the high integration of the semiconductor memory device can be attempted by further decreasing the length in the X-direction for each memory cell MC.

### second Embodiment

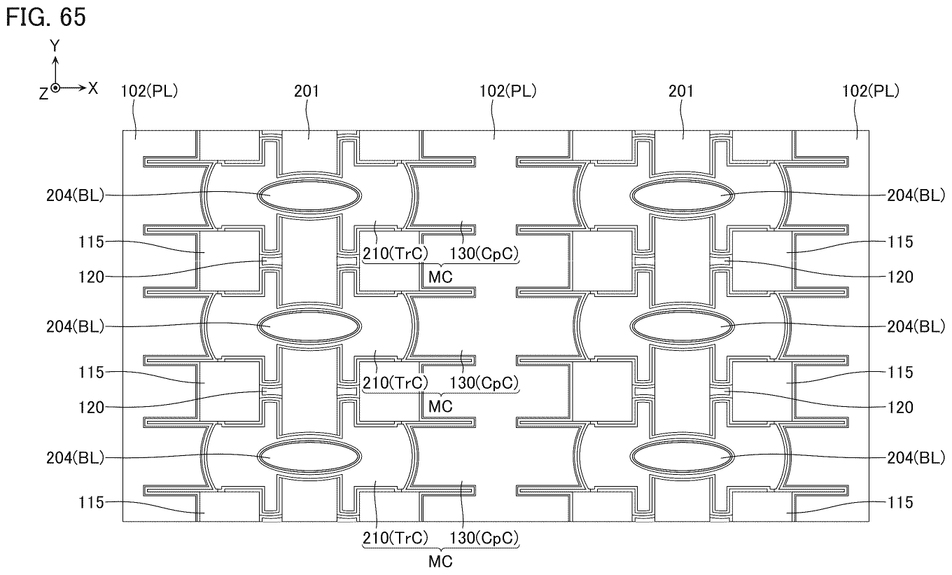

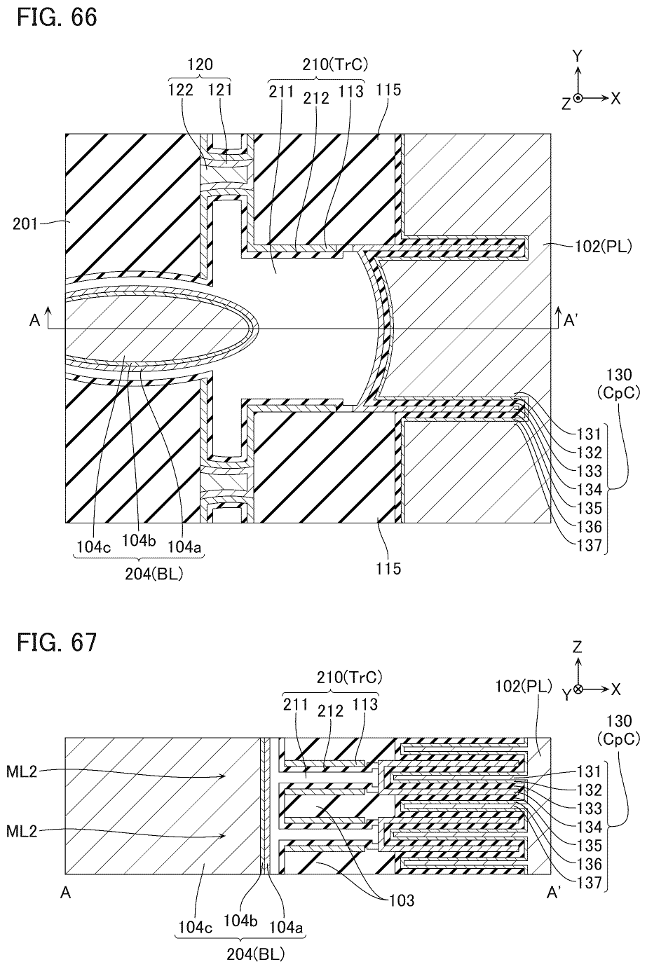

FIG. 65 is a schematic XY cross-sectional view illustrating a configuration of a part of a semiconductor memory device according to a second embodiment. FIG. 66 is a schematic XY cross-sectional view illustrating a configuration of a part of the semiconductor memory device according to the second embodiment. FIG. 67 is a schematic XZ cross-sectional view illustrating a configuration of a part of the semiconductor memory device according to the second embodiment. FIG. 66 illustrates an enlarged part of FIG. 65. FIG. 67 illustrates a cross-sectional surface of the structure illustrated in FIG. 66 taken along the line A-A′ when viewed in an arrow direction. In the following description, same reference numerals are attached to parts similar to those of the first embodiment, and the explanation is omitted.

The semiconductor memory device according to the second embodiment is basically configured similarly to the semiconductor memory device according to the first embodiment. However, a structure of a memory cell array according to the second embodiment is different from the structure of the memory cell array MCA according to the first embodiment.

For example, as illustrated in FIG. 67, the memory cell array according to the second embodiment includes a plurality of memory layers ML2 stacked in the Z-direction. Between the plurality of memory layers ML2, respective insulating layers 103 of silicon oxide (SiO₂) or the like are disposed.

For example, as illustrated in FIG. 65, the memory cell array according to the second embodiment includes a plurality of conductive layers 102 arranged in the X-direction. In a region between two conductive layers 102 adjacent in the X-direction, a plurality of insulating layers 201 and a plurality of via-wirings 204 are alternately arranged in the Y-direction. The plurality of insulating layers 201 and the plurality of via-wirings 204 penetrate the plurality of memory layers ML2 and extend in the Z-direction.

The insulating layer 201 contains, for example, silicon oxide (SiO₂).

The via-wiring 204 is basically configured similarly to the via-wiring 104. However, in the first embodiment, when focusing on the two via-wirings 104 adjacent in the X-direction via the insulating layer 101, one via-wiring 104 is spaced from the other via-wiring 104 via the insulating layer 101. These two via-wirings 104 are electrically connected to the semiconductor layers 111 different from each other. On the other hand, the via-wiring 204 is electrically connected to two semiconductor layers 211 adjacent in the X-direction in common. The via-wiring 204 may have, for example, an approximately ellipse shape or an approximately oval shape when viewed in the Z-direction. A length of the via-wiring 204 in the X-direction may be larger than a length of the via-wiring 204 in the Y-direction. In this embodiment, the wiring members 120 are disposed at positions entirely overlapping with the via-wirings 204 when viewed in the Y-direction.

The memory layer ML2 includes a plurality of transistor structures 210 disposed between the plurality of via-wirings 204 and a plurality of conductive layers 102, a plurality of wiring members 120 each disposed between two transistor structures 210 adjacent in the Y-direction and each connected to these two transistor structures 210, and a plurality of capacitor structures 130 disposed between the plurality of transistor structures 210 and the conductive layers 102.

For example, as illustrated in FIG. 66 and FIG. 67, the transistor structure 210 includes a semiconductor layer 211 connected to an end portion in the X-direction of the via-wiring 204 and extending in the X-direction, an insulating layer 212 disposed on an upper surface, a lower surface, both side surfaces in the Y-direction, and a side surface on one side (insulating layer 201 side) in the X-direction, of the semiconductor layer 211, and a conductive layer 113 disposed on an upper surface, a lower surface, both side surfaces in the Y-direction, and a side surface on one side (insulating layer 201 side) in the X-direction, of the insulating layer 212.

The semiconductor layer 211 and the insulating layer 212 are basically configured similarly to the semiconductor layer 111 and the insulating layer 112. However, for example, as illustrated in FIG. 66, the semiconductor layer 211 and the insulating layer 212 include parts disposed at an outer peripheral surface of the via-wiring 204, and are continuous with the semiconductor layer 211 and the insulating layer 212 of another transistor structure 210 adjacent in the X-direction via these parts.

For example, in the semiconductor memory device according to the first embodiment, when the length of the via-wiring 104 in the X-direction is a length approximately a half of the length of the insulating layer 101 in the X-direction, by employing such a configuration, the high integration of the semiconductor memory device can be attempted by further decreasing the length in the X-direction for each memory cell MC.

### Third Embodiment

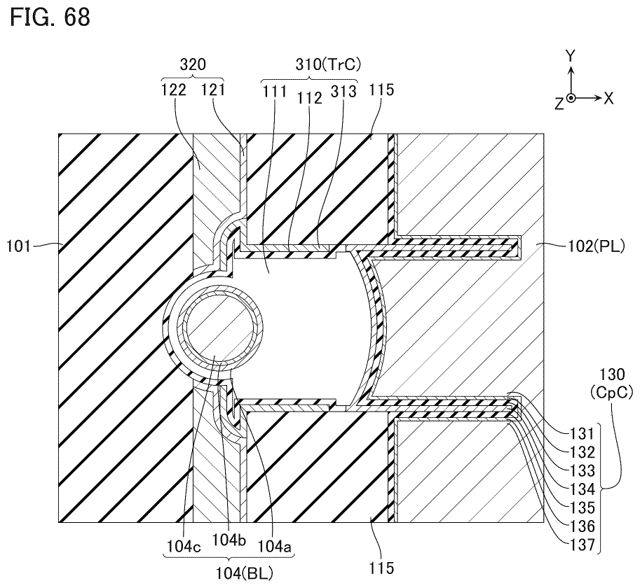

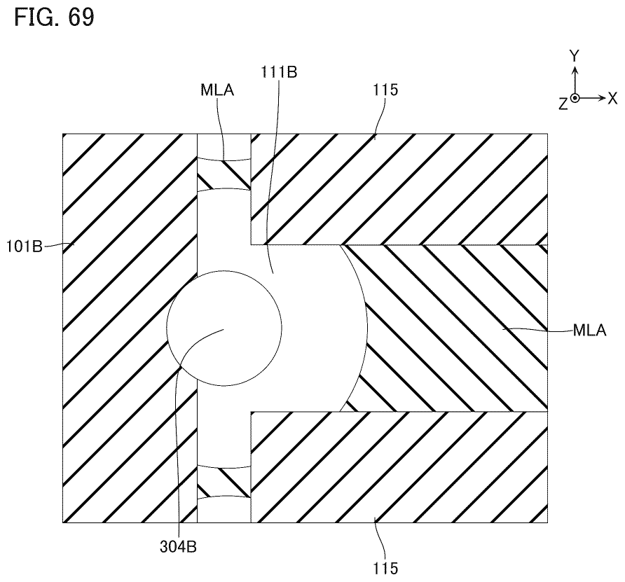

FIG. 68 is a schematic XY cross-sectional view illustrating a configuration of a part of a semiconductor memory device according to a third embodiment. In the following description, same reference numerals are attached to parts similar to those of the first embodiment, and the explanation is omitted.

The semiconductor memory device according to the third embodiment is basically configured similarly to the semiconductor memory device according to the first embodiment. However, the semiconductor memory device according to the third embodiment includes a transistor structure 310 and a wiring member 320 instead of the transistor structure 110 and the wiring member 120.

The transistor structure 310 is basically configured similarly to the transistor structure 110. However, the transistor structure 310 includes a conductive layer 313 instead of the conductive layer 113. The conductive layer 313 is basically configured similarly to the conductive layer 113. However, a side surface of the conductive layer 313 on one side (insulating layer 101 side) in the X-direction is spaced from the insulating layer 101.

The wiring member 320 is basically configured similarly to the wiring member 120. However, in the wiring member 320, a side surface of the wiring member 320 on the other side (conductive layer 102 side) in the X-direction has a part in contact with a side surface of the insulating layer 115 on the one side (insulating layer 101 side) in the X-direction and extending in the Y-direction along this side surface, and a part in contact with a side surface of the conductive layer 313 on the one side (insulating layer 101 side) in the X-direction and extending in the Y-direction along this side surface. Both side surfaces of the conductive layer 313 in the Y-direction are each in contact with the insulating layer 112. In this embodiment, the wiring member 320 is disposed at a position entirely overlapping with the via-wiring 104 when viewed in the Y-direction.

FIG. 69 to FIG. 71 are schematic cross-sectional views for describing a method of manufacturing the semiconductor memory device according to the third embodiment. FIG. 69 to FIG. 71 illustrate cross-sectional surfaces corresponding to FIG. 68.

The semiconductor memory device according to the third embodiment is basically manufactured similarly to the semiconductor memory device according to the first embodiment.

However, in the manufacture of the semiconductor memory device according to the third embodiment, in the process described with reference to FIG. 15 and FIG. 16, as illustrated in FIG. 69, the openings 111A are filled with the sacrifice layers 111B of silicon (Si) or the like, and the opening 104A is filled with another sacrifice layer 304B. This process is performed by, for example, CVD.

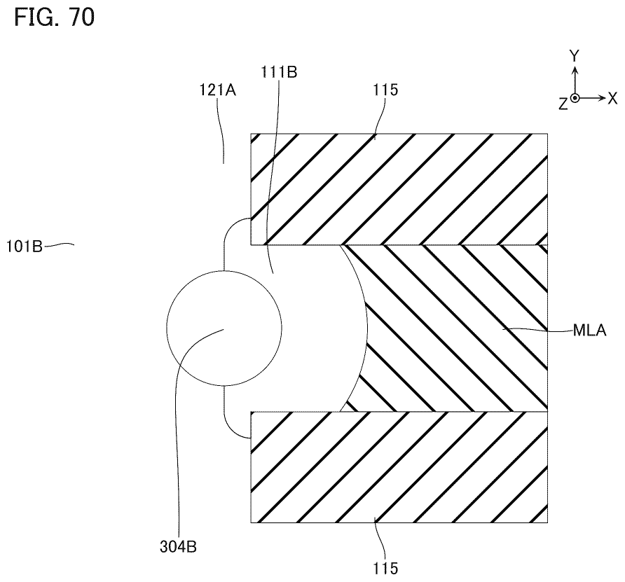

Further, after performing the process described with reference to FIG. 19 and FIG. 20, as illustrated in FIG. 70, parts of the sacrifice layers 111B are removed before performing the process described with reference to FIG. 21 and FIG. 22. This process is performed by, for example, wet etching.

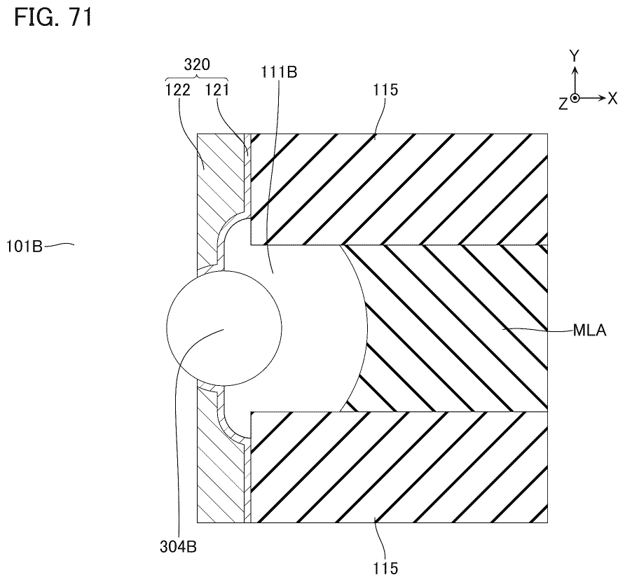

Next, by performing the processes described with reference to FIG. 21 to FIG. 24, as illustrated in FIG. 71, the wiring member 320 is formed.

According to the semiconductor memory device according to the third embodiment, by removing parts of the sacrifice layers 111B in the process described with reference to FIG. 70, the length of the openings 121A in the Y-direction is increased. Therefore, a proportion of the wiring members 320 in the word line WL in the third embodiment is larger than a proportion of the wiring members 120 in the word line WL in the first embodiment. This allows attempting reduction of resistance of the word line WL.

Note that the semiconductor memory device according to the second embodiment may include the wiring member 320 instead of the wiring member 120.

### Fourth Embodiment

In the first embodiment, the side surfaces of the conductive layer 113 and the wiring member 120 on the one side (insulating layer 101 side) in the X-direction are disposed on the other side (conductive layer 102 side) in the X-direction with respect to the end portion of the via-wiring 104 on the one side (insulating layer 101 side) in the X-direction. However, such a configuration is merely an example, and the specific configuration can be adjusted as appropriate. For example, the side surfaces of the conductive layer 113 and the wiring member 120 on the one side (insulating layer 101 side) in the X-direction may be disposed on the one side (insulating layer 101 side) in the X-direction with respect to the end portion of the via-wiring 104 at the one side (insulating layer 101 side) in the X-direction. The same applies to the third embodiment.

As a semiconductor memory device according to a fourth embodiment, such a configuration is exemplified below.

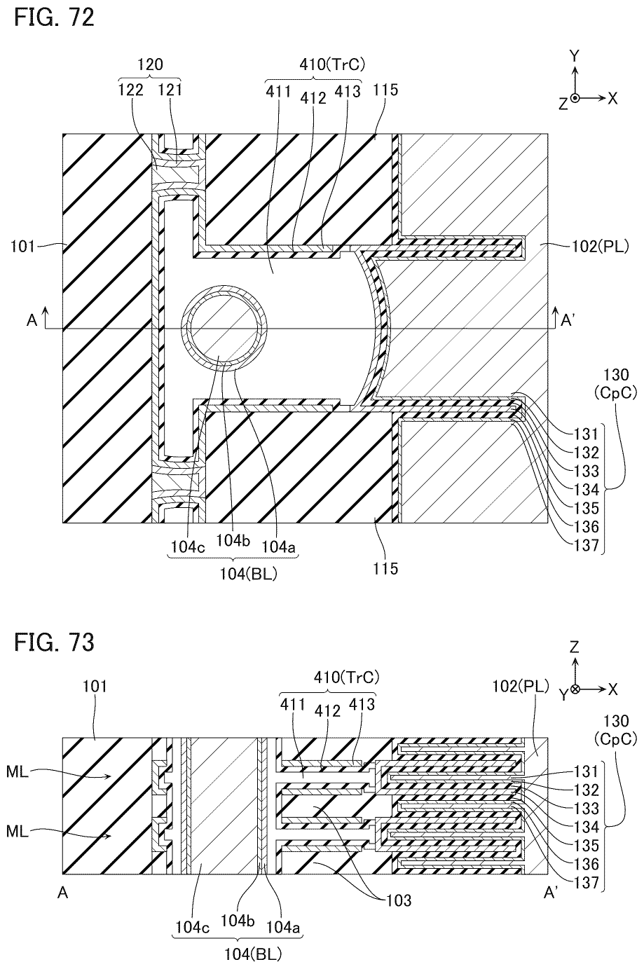

FIG. 72 is a schematic XY cross-sectional view illustrating a configuration of a part of the semiconductor memory device according to the fourth embodiment. FIG. 73 is a schematic XZ cross-sectional view illustrating a configuration of a part of the semiconductor memory device according to the fourth embodiment. FIG. 73 illustrates a cross-sectional surface of the structure illustrated in FIG. 72 taken along the line A-A′ when viewed in an arrow direction. In the following description, same reference numerals are attached to parts similar to those of the first embodiment, and the explanation is omitted.

The semiconductor memory device according to fourth embodiment is basically configured similarly to the semiconductor memory device according to the first embodiment. However, the semiconductor memory device according to fourth embodiment includes a transistor structure 410 instead of the transistor structure 110.

The transistor structure 410 is basically configured similarly to the transistor structure 110. However, the transistor structure 410 includes a semiconductor layer 411, an insulating layer 412, and a conductive layer 413 instead of the semiconductor layer 111, the insulating layer 112, and the conductive layer 113.

The semiconductor layer 411, the insulating layer 412, and the conductive layer 413 are basically configured similarly to the semiconductor layer 111, the insulating layer 112, and the conductive layer 113. However, in the semiconductor layer 411, the insulating layer 412, and the conductive layer 413, their entire side surfaces on the one side (insulating layer 101 side) in the X-direction are linearly formed along the side surface of the insulating layer 101 in the X-direction.

In this embodiment, the side surfaces of the conductive layer 413 and the wiring member 120 on the one side (insulating layer 101 side) in the X-direction are disposed on the one side (insulating layer 101 side) in the X-direction with respect to the end portion of the via-wiring 104 on the one side (insulating layer 101 side) in the X-direction. Additionally, a side surface of the wiring member 120 on the other side (conductive layer 102 side) in the X-direction is disposed on the one side (insulating layer 101 side) in the X-direction with respect to the end portion of the via-wiring 104 on the other side (conductive layer 102 side) in the X-direction. That is, in this embodiment, the wiring member 120 is disposed at a position partially overlapping with the via-wiring 104 when viewed in the Y-direction.

Note that the semiconductor memory device according to the fourth embodiment may include the wiring member 320 (FIG. 68) instead of the wiring member 120.

### Fifth Embodiment

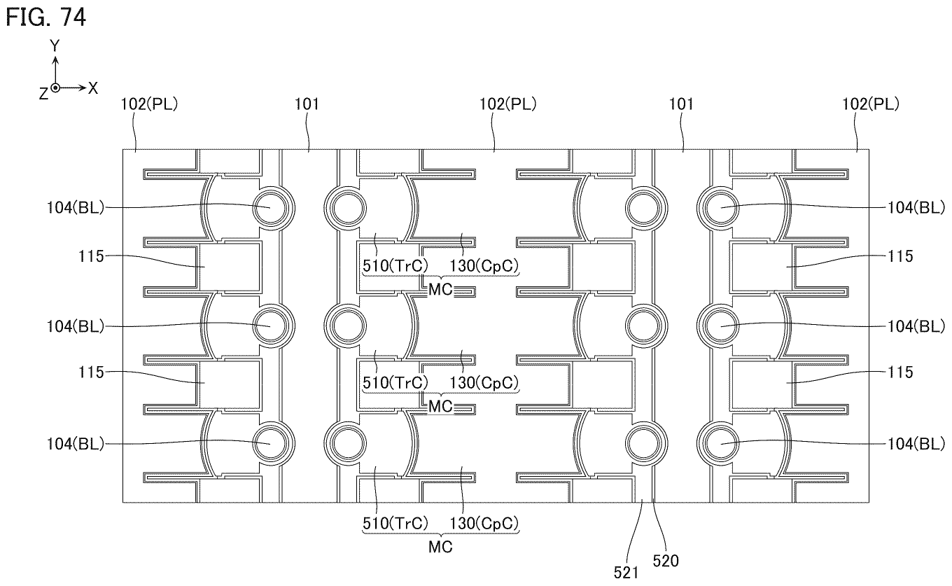

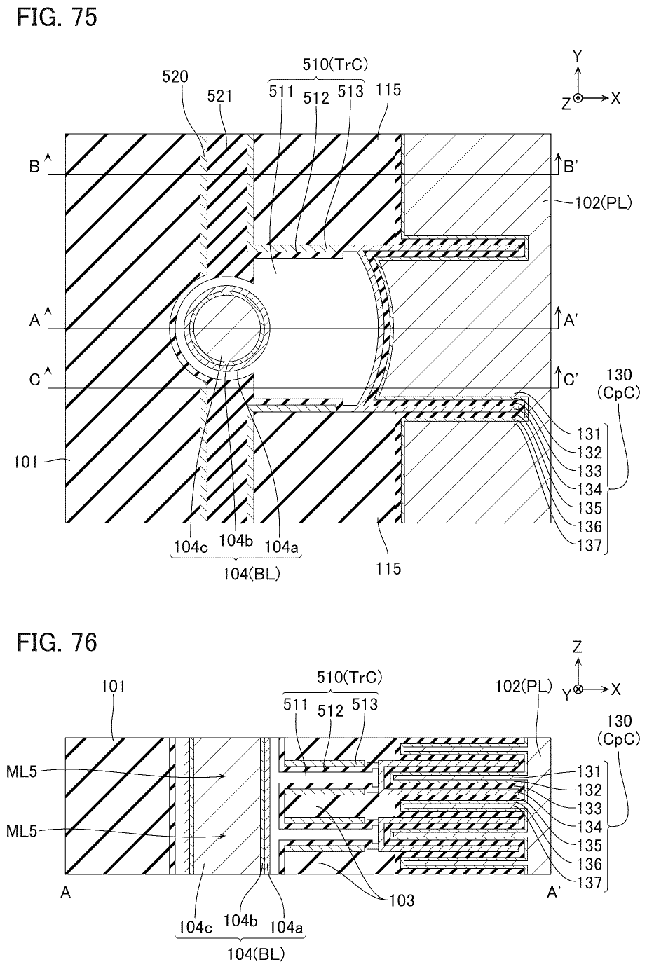

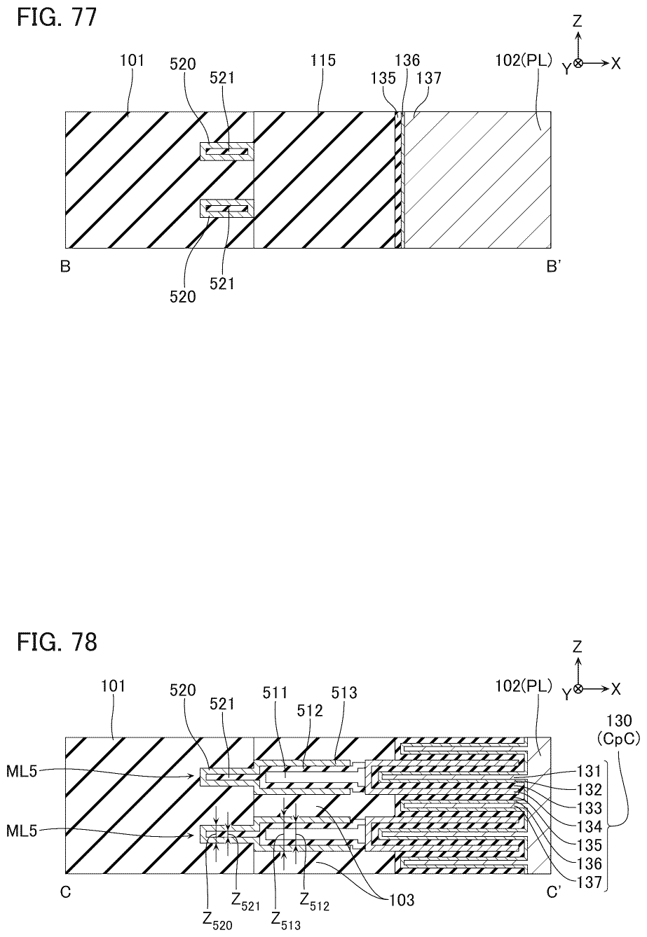

FIG. 74 is a schematic XY cross-sectional view illustrating a configuration of a part of a semiconductor memory device according to a fifth embodiment. FIG. 75 is a schematic XY cross-sectional view illustrating a configuration of a part of the semiconductor memory device according to the fifth embodiment. FIG. 76 to FIG. 78 are schematic XZ cross-sectional views illustrating configurations of parts of the semiconductor memory device according to the fifth embodiment. FIG. 75 illustrates an enlarged part of FIG. 74. FIG. 76 illustrates a cross-sectional surface of the structure illustrated in FIG. 75 taken along the line A-A′ when viewed in an arrow direction. FIG. 77 illustrates a cross-sectional surface of the structure illustrated in FIG. 75 taken along the line B-B′ when viewed in an arrow direction. FIG. 78 illustrates a cross-sectional surface of the structure illustrated in FIG. 75 taken along the line C-C′ when viewed in an arrow direction. In the following description, same reference numerals are attached to parts similar to those of the first embodiment, and the explanation is omitted.

The semiconductor memory device according to the fifth embodiment is basically configured similarly to the semiconductor memory device according to the first embodiment. However, the semiconductor memory device according to the fifth embodiment includes a memory layer ML5 instead of the memory layer ML. The memory layer ML5 is basically configured similarly to the memory layer ML. However, the memory layer ML5 includes a transistor structure 510, a wiring member 520, and an insulating member 521 instead of the transistor structure 110 and the wiring member 120.

The transistor structure 510 is basically configured similarly to the transistor structure 110. However, the transistor structure 510 includes a semiconductor layer 511, an insulating layer 512, and a conductive layer 513 instead of the semiconductor layer 111, the insulating layer 112, and the conductive layer 113. The semiconductor layer 511, the insulating layer 512, and the conductive layer 513 are basically configured similarly to the semiconductor layer 111, the insulating layer 112, and the conductive layer 113. However, the semiconductor layer 511, the insulating layer 512, and the conductive layer 513 are not disposed in the regions between the insulating layers 115 and the insulating layer 101.

The wiring member 520 extends in the Y-direction, and is continuous with two conductive layers 513 adjacent in the Y-direction. A side surface of the wiring member 520 on the one side (insulating layer 101 side) in the X-direction is in contact with the insulating layer 101, and a side surface of the wiring member 520 on the other side (conductive layer 102 side) in the X-direction is in contact with the insulating layer 115. A plurality of the wiring members 520 arranged in the Y-direction are mutually electrically connected via a plurality of the conductive layers 513 arranged in the Y-direction. The plurality of wiring members 520 and the plurality of conductive layers 513 alternately arranged in the Y-direction function as, for example, the word lines WL. The wiring member 520 includes, for example, a barrier conductive film of titanium nitride (TiN) or the like.

The insulating member 521 extends in the Y-direction, and is continuous with two insulating layers 512 adjacent in the Y-direction. The wiring member 520 is in contact with an upper surface, a lower surface, and both side surfaces in the X-direction, of the insulating member 521. A plurality of the insulating members 521 are alternately arranged with the plurality of transistor structures 510 in the Y-direction. The insulating member 521 contains, for example, a material similar to that of the insulating layer 512.

For example, as illustrated in FIG. 78, a length Z₅₂₀ in the Z-direction of the wiring member 520 is smaller than a length Z₅₁₃ in the Z-direction of the conductive layer 513. A length Z₅₂₁ in the Z-direction of the insulating member 521 is smaller than a length Z₅₁₂ in the Z-direction of the insulating layer 512.

In this embodiment, a side surface of the wiring member 520 on the one side (insulating layer 101 side) in the X-direction is disposed on the other side (conductive layer 102 side) in the X-direction with respect to the end portion of the via-wiring 104 on the one side (insulating layer 101 side) in the X-direction. A side surface of the wiring member 520 on the other side (conductive layer 102 side) in the X-direction is disposed on the one side (insulating layer 101 side) in the X-direction with respect to the end portion of the via-wiring 104 on the other side (conductive layer 102 side) in the X-direction. That is, in this embodiment, the wiring member 520 is disposed at a position entirely overlapping with the via-wiring 104 when viewed in the Y-direction.

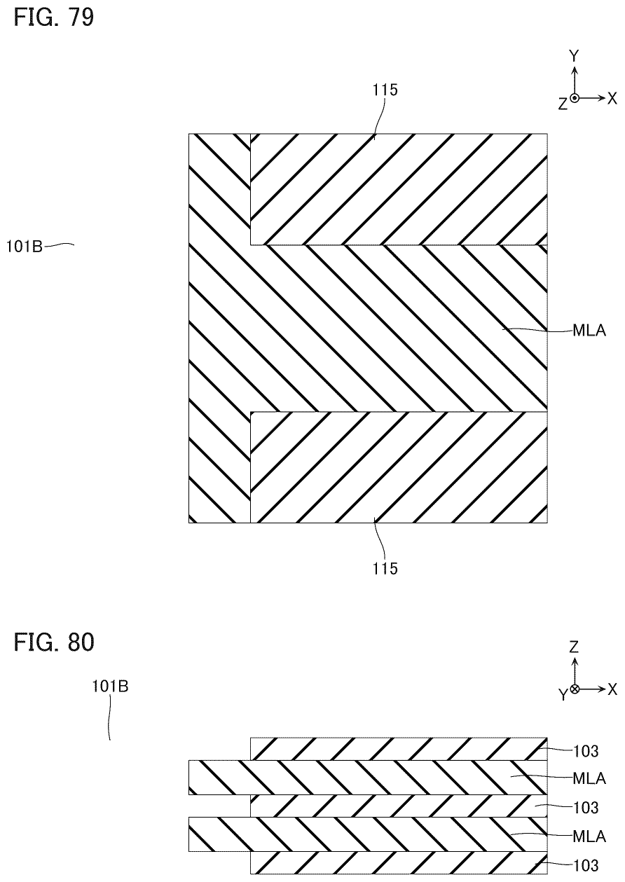

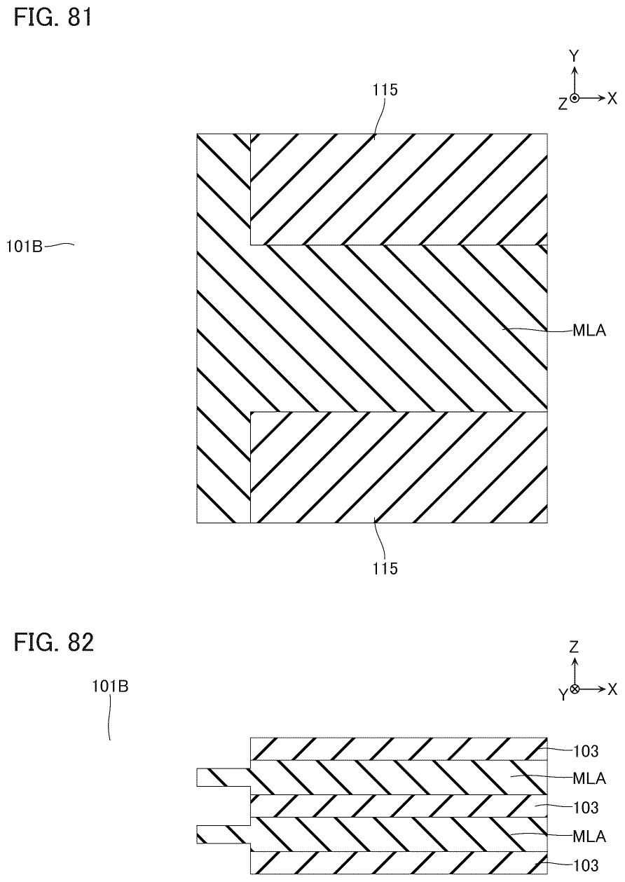

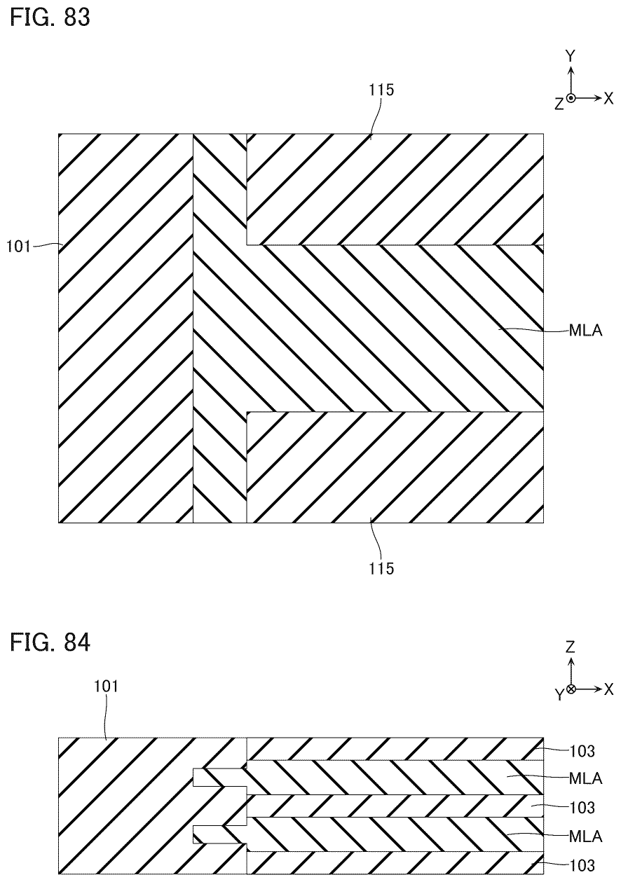

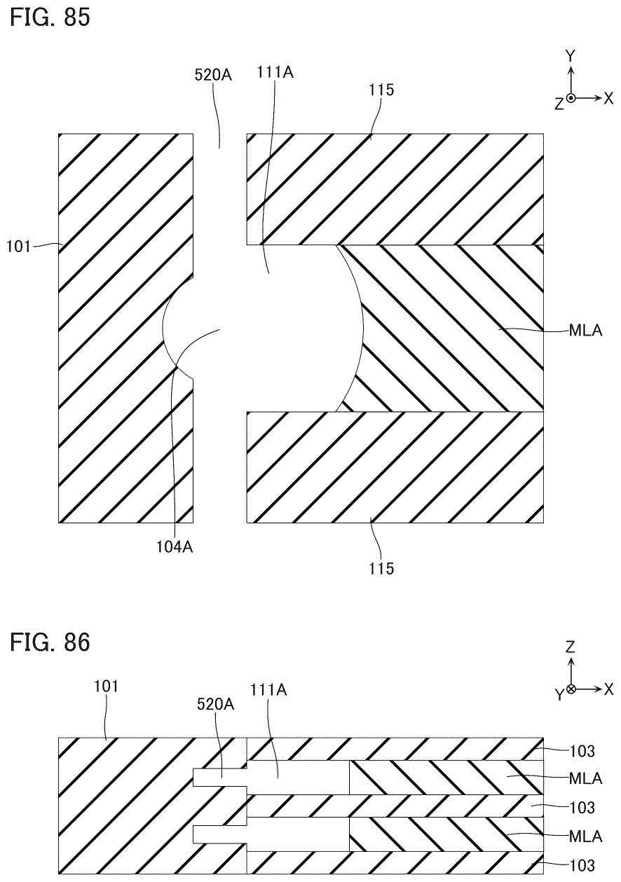

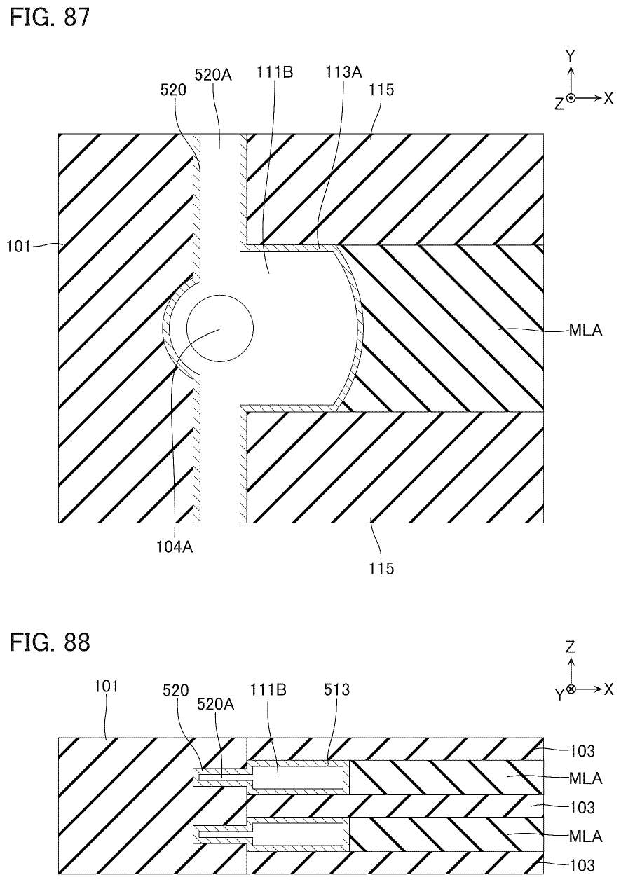

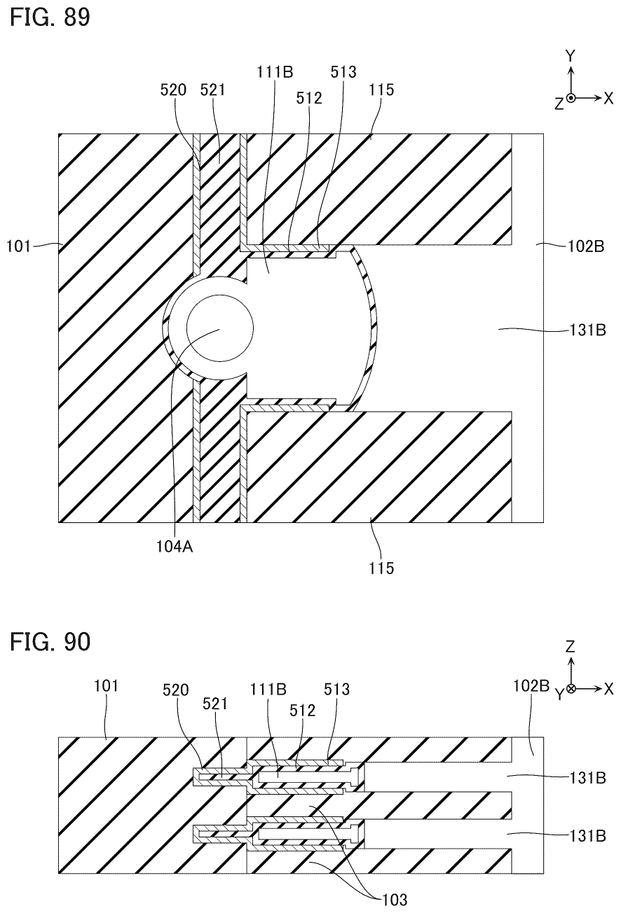

FIG. 79 to FIG. 90 are schematic cross-sectional views for describing a method of manufacturing the semiconductor memory device according to the fifth embodiment. FIG. 79, FIG. 81, FIG. 83, FIG. 85, FIG. 87, and FIG. 89 illustrate cross-sectional surfaces corresponding to FIG. 75. FIG. 80, FIG. 82, FIG. 84, FIG. 86, FIG. 88, and FIG. 90 illustrate cross-sectional surfaces corresponding to FIG. 78.

In the manufacture of the semiconductor memory device according to the fifth embodiment, for example, the manufacturing method according to the first embodiment is performed up to the process described with reference to FIG. 9 and FIG. 10.

Next, as illustrated in FIG. 79 and FIG. 80, the sacrifice layer 101A is removed to form an opening 101B. Parts of the insulating layers 103 are removed to expose the upper surfaces and the lower surfaces of the sacrifice layers MLA at parts corresponding to the wiring member 520. This process is performed by, for example, wet etching.

Next, as illustrated in FIG. 81 and FIG. 82, parts of the sacrifice layers MLA are removed via the opening 101B. Thus, a length of parts corresponding to the wiring members 520 of the sacrifice layers MLA in the Z-direction is decreased. This process is performed by, for example, wet etching.

Next, as illustrated in FIG. 83 and FIG. 84, the insulating layer 101 is formed inside the opening 101B. This process is performed by, for example, CVD.

Next, as illustrated in FIG. 85 and FIG. 86, the processes described with reference to FIG. 11 to FIG. 14 are performed. In this process, the sacrifice layer MLA is not left between the two openings 111A adjacent in the Y-direction. Thus, openings 111A are formed at positions corresponding to the transistor structures 510. Openings 520A are formed at positions corresponding to the wiring members 520. A length of the openings 520A in the Z-direction is smaller than a length of the openings 111A in the Z-direction. At the phase where this process is performed, a plurality of openings 111A arranged in the Y-direction are mutually communicated via the opening 520A.

Next, as illustrated in FIG. 87 and FIG. 88, the process described with reference to FIG. 27 and FIG. 28 is performed.

Next, as illustrated in FIG. 89 and FIG. 90, the processes described with reference to FIG. 29 to FIG. 42 are performed. In the process illustrated in FIG. 41 and FIG. 42, the insulating layer 512 and the insulating member 521 are formed instead of the insulating layer 112. In this process, the openings 520A are filled with the insulating members 521. On the other hand, the openings 111A are not filled with the insulating layers 512. Thus, the plurality of openings 111A arranged in the Y-direction are spatially separated via the insulating members 521.

Then, the processes after the process described with reference to FIG. 43 and FIG. 44 in the manufacturing method according to the first embodiment are performed, thereby manufacturing the semiconductor memory device according to the fifth embodiment.

Also with this configuration, similarly to the first embodiment, the high integration of the semiconductor memory device can be attempted by decreasing the length in the X-direction for each memory cell MC.

In the semiconductor memory device according to the fifth embodiment, it is not necessary to perform the processes described with reference to FIG. 21 to FIG. 24 in the manufacturing processes of the semiconductor memory device according to the first embodiment. This allows the manufacture at low cost compared with the semiconductor memory device according to the first embodiment.

### Sixth Embodiment

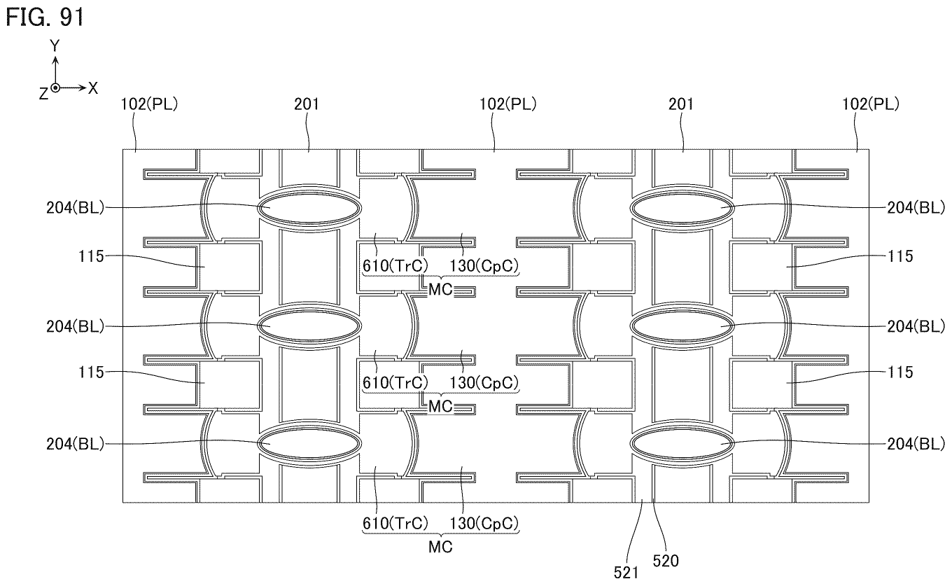

FIG. 91 is a schematic XY cross-sectional view illustrating a configuration of a part of a semiconductor memory device according to a sixth embodiment. In the following description, same reference numerals are attached to parts similar to those of the fifth embodiment or the second embodiment, and the explanation is omitted.

The semiconductor memory device according to the sixth embodiment is basically configured similarly to the semiconductor memory device according to the fifth embodiment. However, a structure of a memory cell array according to the sixth embodiment is different from the structure of the memory cell array according to the fifth embodiment.

For example, as illustrated in FIG. 91, the memory cell array according to the sixth embodiment includes a plurality of conductive layers 102 arranged in the X-direction. In a region between two conductive layers 102 adjacent in the X-direction, a plurality of insulating layers 201 and a plurality of via-wirings 204 alternately arranged in the Y-direction are disposed. The plurality of insulating layers 201 and the plurality of via-wirings 204 penetrate a plurality of memory layers ML and extend in the Z-direction.

The memory layer according to the sixth embodiment includes a plurality of transistor structures 610 disposed between the plurality of via-wirings 204 and the plurality of conductive layers 102, a plurality of wiring members 520 each disposed between two transistor structures 610 adjacent in the Y-direction and each connected to these two transistor structures 610, and a plurality of capacitor structures 130 disposed between the plurality of transistor structures 610 and the conductive layers 102.

The transistor structure 610 is basically configured similarly to the transistor structure 510. However, configurations corresponding to the semiconductor layer 511 and the insulating layer 512 in the transistor structure 610 have parts disposed on the outer peripheral surface of the via-wiring 204, and are continuous with configurations corresponding to the semiconductor layer 511 and the insulating layer 512 in another transistor structure 610 adjacent in the X-direction via these parts.

For example, in the semiconductor memory device according to the fifth embodiment, when the length of the via-wiring 104 in the X-direction is a length approximately a half of the length of the insulating layer 101 in the X-direction, by employing such a configuration, the high integration of the semiconductor memory device can be attempted by further decreasing the length in the X-direction for each memory cell MC.

### Seventh Embodiment

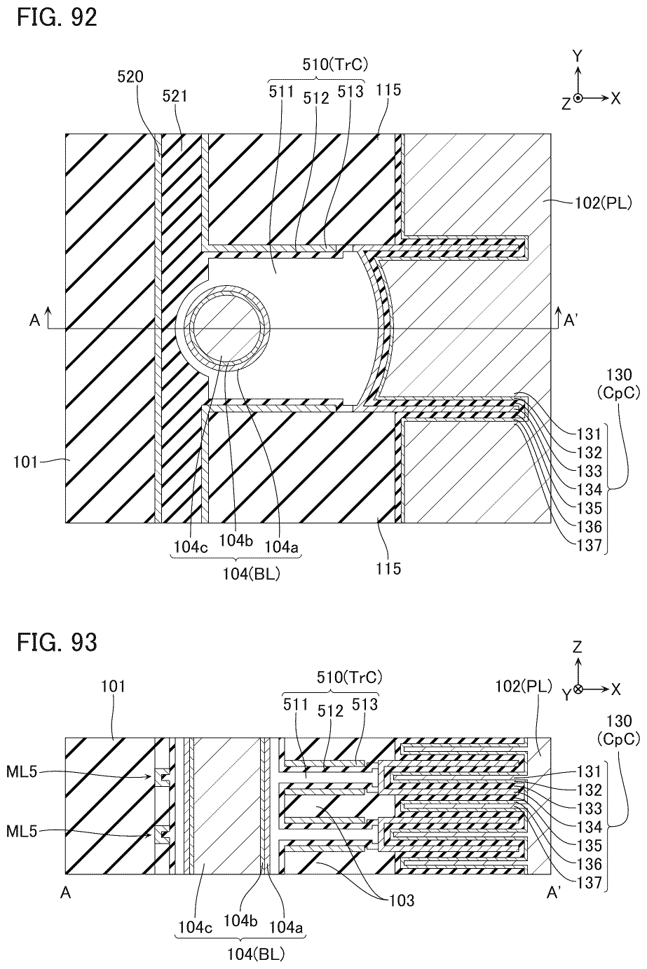

FIG. 92 is a schematic XY cross-sectional view illustrating a configuration of a part of a semiconductor memory device according to a seventh embodiment. FIG. 93 is a schematic XZ cross-sectional view illustrating a configuration of a part of the semiconductor memory device according to the seventh embodiment. FIG. 93 illustrates a cross-sectional surface of the structure illustrated in FIG. 92 taken along the line A-A′ when viewed in an arrow direction. In the following description, same reference numerals are attached to parts similar to those of the fifth embodiment, and the explanation is omitted.

The semiconductor memory device according to the seventh embodiment is basically configured similarly to the semiconductor memory device according to the fifth embodiment.

However, in the seventh embodiment, a side surface on one side (insulating layer 101 side) in the X-direction of the wiring member 520 is disposed on the one side (insulating layer 101 side) in the X-direction with respect to an end portion of the via-wiring 104 on the one side (insulating layer 101 side) in the X-direction. Additionally, a side surface of the wiring member 520 on the other side (conductive layer 102 side) in the X-direction is disposed on the one side (insulating layer 101 side) in the X-direction with respect to an end portion of the via-wiring 104 on the other side (conductive layer 102 side) in the X-direction. That is, in this embodiment, the wiring member 520 is disposed at a position partially overlapping with the via-wiring 104 when viewed in the Y-direction.

In the seventh embodiment, a plurality of the wiring members 520 arranged in the Y-direction are mutually continuous. Similarly, a plurality of the insulating members 521 arranged in the Y-direction are mutually continuous.

### Eighth Embodiment

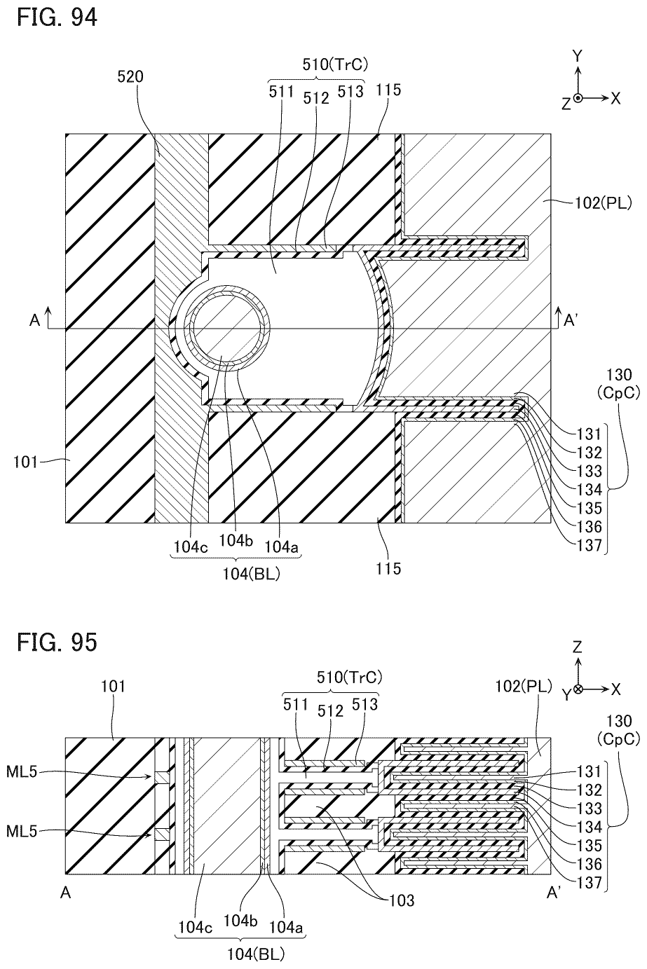

FIG. 94 is a schematic XY cross-sectional view illustrating a configuration of a part of a semiconductor memory device according to an eighth embodiment. FIG. 95 is a schematic XZ cross-sectional view illustrating a configuration of a part of the semiconductor memory device according to the eighth embodiment. FIG. 95 illustrates a cross-sectional surface of the structure illustrated in FIG. 94 taken along the line A-A′ when viewed in an arrow direction. In the following description, same reference numerals are attached to parts similar to those of the seventh embodiment, and the explanation is omitted.

The semiconductor memory device according to the eighth embodiment is basically configured similarly to the semiconductor memory device according to the seventh embodiment. However, the semiconductor memory device according to the eighth embodiment does not include the insulating member 521.

The semiconductor memory device according to the eighth embodiment can be manufactured by, for example, filling the opening 520A with the wiring member 520 in the process described with reference to FIG. 87 and FIG. 88.

In the semiconductor memory device according to the eighth embodiment, a side surface of the wiring member 520 on one side (insulating layer 101 side) in the X-direction may be disposed on the other side (conductive layer 102 side) in the X-direction with respect to an end portion of the via-wiring 104 on the one side (insulating layer 101 side) in the X-direction. That is, also in the eighth embodiment, the wiring member 520 may be disposed at a position entirely overlapping with the via-wiring 104 when viewed in the Y-direction.

The semiconductor memory device according to the sixth embodiment does not need to include the insulating member 521 similarly to the semiconductor memory device according to the eighth embodiment.

### Ninth Embodiment

In the first embodiment to the eighth embodiment, an example in which one memory cell MC includes one transistor TrC and one capacitor CpC is described. However, such a configuration is merely an example, and the specific configuration can be adjusted as appropriate. As a semiconductor memory device according to the ninth embodiment, an example in which one memory cell includes a plurality of transistors is described below.

### Circuit Configuration

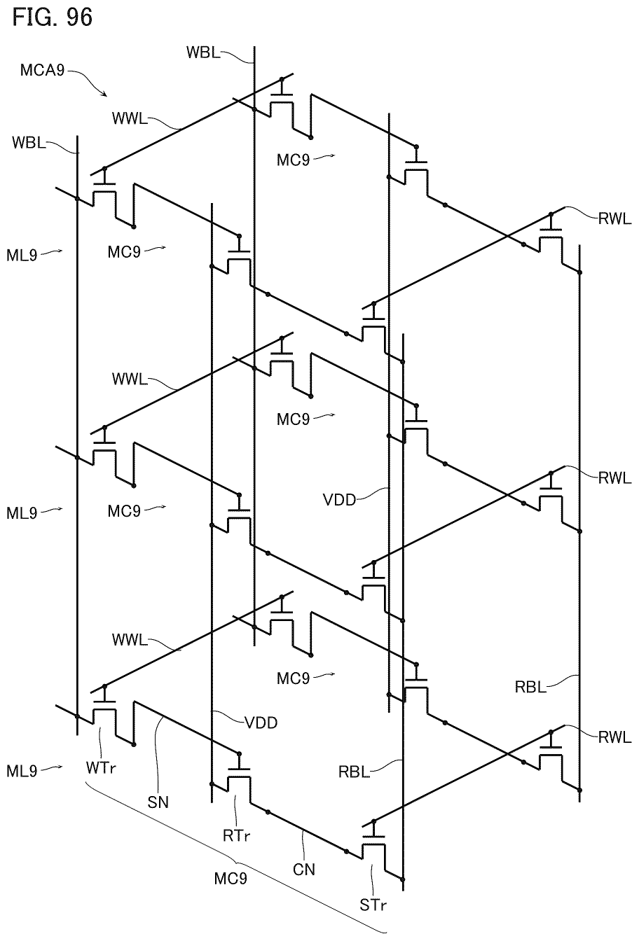

FIG. 96 is a schematic circuit diagram illustrating a configuration of a part of the semiconductor memory device according to the ninth embodiment.

As illustrated in FIG. 96, the semiconductor memory device according to the embodiment includes a memory cell array MCA9. The memory cell array MCA9 includes a plurality of memory layers ML9, a plurality of write bit lines WBL connected to these plurality of memory layers ML9, a plurality of voltage supply lines VDD connected to the plurality of memory layers ML9, and a plurality of read bit lines RBL connected to the plurality of memory layers ML9. The voltage supply lines VDD may apply the power supply voltage Vdd, or may apply a ground voltage Vss.

Each of the memory layers ML9 includes a write word line WWL, a read word line RWL, and a plurality of memory cells MC9 connected to these write word line WWL and read word line RWL. Each of the memory cells MC9 includes a write transistor WTr, a sense node SN, a read transistor RTr, a connection node CN, and a switch transistor STr.

The write transistor WTr is, for example, a field-effect type NMOS transistor. The write transistor WTr has one electrode connected to the write bit line WBL. The write transistor WTr has the other electrode connected to the sense node SN. The one and the other electrodes of the write transistor WTr function as a source electrode or a drain electrode corresponding to a voltage applied to the write transistor WTr. The write transistor WTr has a gate electrode connected to the write word line WWL.

The read transistor RTr is, for example, a field-effect type NMOS transistor. The read transistor RTr has one electrode connected to the voltage supply line VDD. The read transistor RTr has the other electrode connected to the connection node CN. The one and the other electrodes of the read transistor RTr function as a source electrode or a drain electrode corresponding to a voltage applied to the read transistor RTr. The read transistor RTr has a gate electrode connected to the sense node SN.

The switch transistor STr is, for example, a field-effect type NMOS transistor. The switch transistor STr has one electrode connected to the read bit line RBL. The switch transistor STr has the other electrode connected to the connection node CN. The one and the other electrodes of the switch transistor STr function as a source electrode or a drain electrode corresponding to a voltage applied to the switch transistor STr. The switch transistor STr has a gate electrode connected to the read word line RWL.

### Structure

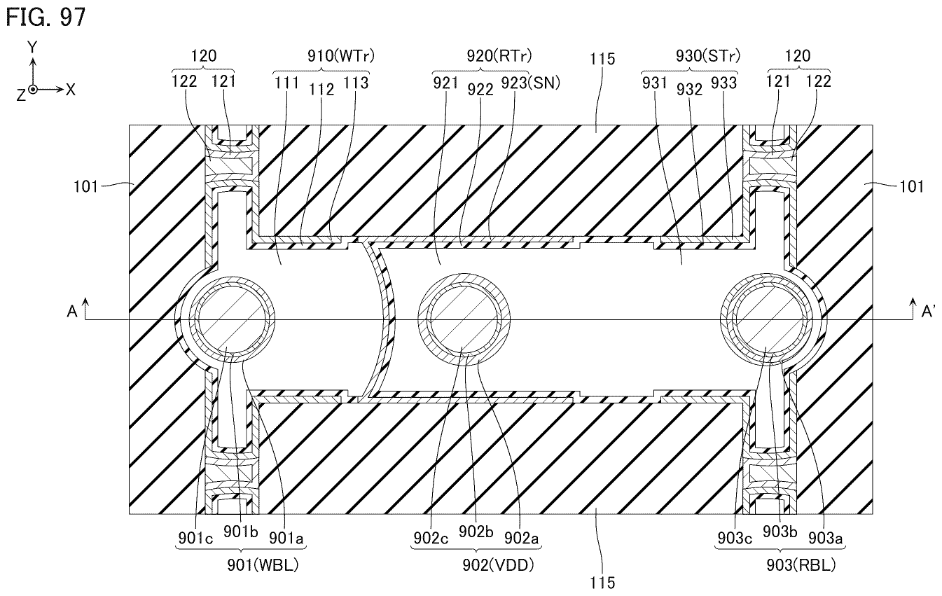

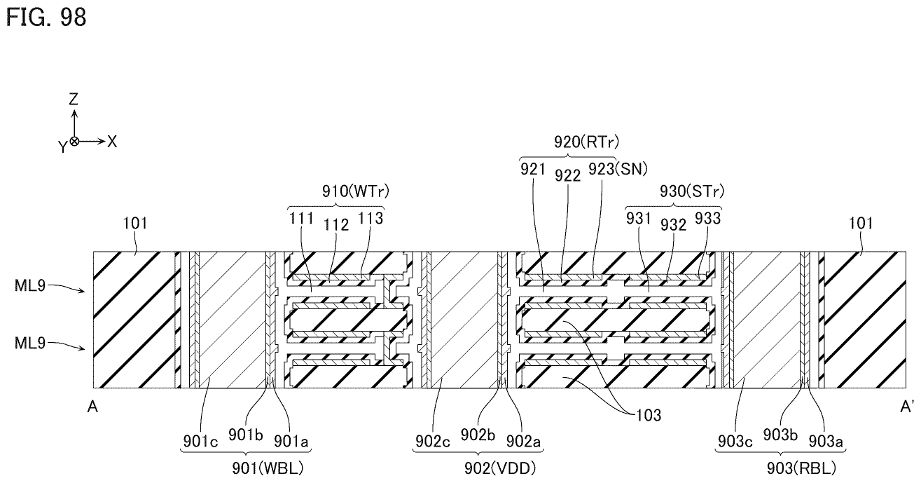

FIG. 97 is a schematic XY cross-sectional view illustrating a configuration of a part of the semiconductor memory device according to the ninth embodiment. FIG. 98 is a schematic cross-sectional view illustrating a configuration of a part of the semiconductor memory device, and illustrates the structure illustrated in FIG. 97 taken along the line A-A′ when viewed in an arrow direction.

The memory cell array MCA9 includes a plurality of memory layers ML9 arranged in the Z-direction. Insulating layers 103 of silicon oxide (SiO₂) or the like are each disposed between the plurality of memory layers ML9.

The memory cell array MCA9 includes a plurality of insulating layers 101 alternately arranged with the plurality of memory layers ML9 and the plurality of insulating layers stacked in the Z-direction in the X-direction and extending in the Y-direction and the Z-direction.

The memory cell array MCA9 includes via-wirings 901, 902, 903. The via-wiring 901 functions as a write bit line WBL. The via-wiring 902 functions as a voltage supply line VDD. The via-wiring 903 functions as a read bit line RBL. The via-wirings 901, 902, 903 are arranged in the X-direction in this order between two insulating layers 101 adjacent in the X-direction, penetrate the plurality of memory layers ML9, and extend in the Z-direction.

The via-wiring 901 includes, for example, a conductive oxide film 901a containing a conductive oxide, a barrier conductive film 901b of titanium nitride (TiN) or the like, and a conductive member 901c of tungsten (W) or the like. The via-wiring 901 may contain ruthenium (Ru), iridium (Ir), or another metal instead of the conductive oxide film 901a. The via-wiring 901 may contain only the conductive oxide, or may contain only ruthenium (Ru), iridium (Ir), or another metal.

The conductive member 901c has an approximately columnar shape extending in the Z-direction. The barrier conductive film 901b has an approximately cylindrical shape extending in the Z-direction along an outer peripheral surface of the conductive member 901c. The conductive oxide film 901a has an approximately cylindrical shape extending in the Z-direction along an outer peripheral surface of the barrier conductive film 901b.

The via-wiring 902 includes, for example, a conductive oxide film 902a containing a conductive oxide, a barrier conductive film 902b of titanium nitride (TiN) or the like, and a conductive member 902c of tungsten (W) or the like. The via-wiring 902 may contain ruthenium (Ru), iridium (Ir), or another metal instead of the conductive oxide film 902a. The via-wiring 902 may contain only the conductive oxide, or may contain only ruthenium (Ru), iridium (Ir), or another metal.

The conductive member 902c has an approximately columnar shape extending in the Z-direction. The barrier conductive film 902b has an approximately cylindrical shape extending in the Z-direction along an outer peripheral surface of the conductive member 902c. The conductive oxide film 902a has an approximately cylindrical shape extending in the Z-direction along an outer peripheral surface of the barrier conductive film 902b.

The via-wiring 903 includes, for example, a conductive oxide film 903a containing a conductive oxide, a barrier conductive film 903b of titanium nitride (TiN) or the like, and a conductive member 903c of tungsten (W) or the like. The via-wiring 903 may contain ruthenium (Ru), iridium (Ir), or another metal instead of the conductive oxide film 903a. The via-wiring 903 may contain only the conductive oxide, or may contain only ruthenium (Ru), iridium (Ir), or another metal.

The conductive member 903c has an approximately columnar shape extending in the Z-direction. The barrier conductive film 903b has an approximately cylindrical shape extending in the Z-direction along an outer peripheral surface of the conductive member 903c. The conductive oxide film 903a has an approximately cylindrical shape extending in the Z-direction along an outer peripheral surface of the barrier conductive film 903b.

The memory layer ML9 includes a transistor structure 910 disposed at a position corresponding to the via-wiring 901, a transistor structure 920 disposed at a position corresponding to the via-wiring 902, and a transistor structure 930 disposed at a position corresponding to the via-wiring 903. In the example of the drawing, the transistor structures 910, 920, 930 are arranged in the X-direction. The memory layer ML9 includes a plurality of wiring members 120 each disposed between two transistor structures 910 adjacent in the Y-direction and each connected to these two transistor structures 910, and a plurality of wiring members 120 each disposed between two transistor structures 930 adjacent in the Y-direction and each connected to these two transistor structures 930.

The transistor structure 910 is basically configured similarly to the transistor structure 110. However, the semiconductor layer 111, the insulating layer 112, and the conductive layer 113 in the transistor structure 910 function as a channel region, a gate insulating film, and a gate electrode of the write transistor WTr, respectively. The conductive layer 113 also functions as a part of the write word line WWL.

The transistor structure 920 includes a semiconductor portion 921 connected to an outer peripheral surface of the via-wiring 902 and extending in the X-direction, an insulating portion 922 disposed on an upper surface, a lower surface, both side surfaces in the Y-direction, and a side surface on one side (transistor structure 910 side) in the X-direction, of the semiconductor portion 921, and a conductive layer 923 disposed on an upper surface, a lower surface, both side surfaces in the Y-direction, and a side surface on the one side (transistor structure 910 side) in the X-direction, of the insulating portion 922.

The transistor structure 930 includes a semiconductor portion 931 connected to an outer peripheral surface of the via-wiring 903 and extending in the X-direction, an insulating portion 932 disposed on an upper surface, a lower surface, both side surfaces in the Y-direction, and a side surface on the other side in the X-direction (opposite side of the transistor structure 910), of the semiconductor portion 931, and a conductive layer 933 disposed on an upper surface, a lower surface, both side surfaces in the Y-direction, and a side surface on the other side in the X-direction (opposite side of the transistor structure 910), of the insulating portion 932.

The semiconductor portion 921 and the semiconductor portion 931 are continuous and directly connected to one another. Each of the semiconductor portion 921 and the semiconductor portion 931 is a part of one semiconductor layer extending in the X-direction. Similarly, the insulating portion 922 and the insulating portion 932 are continuous and directly connected to one another. Each of the insulating portion 922 and the insulating portion 932 is a part of one insulating layer.

In the XY cross-sectional surface illustrated in FIG. 97, side surfaces of the semiconductor portion 921, the insulating portion 922, and the conductive layer 923 on the one side (transistor structure 910 side) in the X-direction may be formed along a circle having the center position of the via-wiring 901 as the center. Side surfaces of the semiconductor portion 931, the insulating portion 932, and the conductive layer 933 on the other side (opposite side of the transistor structure 910) in the X-direction may have a part linearly formed along a side surface of the insulating layer 101 on the one side in the X-direction and a part formed along a circle having the center position of the via-wiring 903 as the center. Both side surfaces of the semiconductor portion 921, the insulating portion 922, the conductive layer 923, the semiconductor portion 931, the insulating portion 932, and the conductive layer 933 in the Y-direction may be linearly formed along side surfaces of the insulating layer 115 in the Y-direction.

The semiconductor portion 921 functions as, for example, a channel region of the read transistor RTr (FIG. 96). The semiconductor portion 931 functions as, for example, a channel region of the switch transistor STr (FIG. 96). The semiconductor portions 921, 931 may be, for example, a semiconductor containing at least one element of gallium (Ga) or aluminum (Al) and containing indium (In), zinc (Zn), and oxygen (O), or may be another oxide semiconductor. A plurality of the semiconductor portions 921 arranged in the Z-direction are connected to the via-wiring 902 extending in the Z-direction in common. A plurality of the semiconductor portions 931 arranged in the Z-direction are connected to the via-wiring 903 extending in the Z-direction in common.

The insulating portion 922 functions as, for example, a gate insulating film of the read transistor RTr (FIG. 96). The insulating portion 932 functions as, for example, a gate insulating film of the switch transistor STr (FIG. 96). The insulating portions 922, 932 contain, for example, silicon oxide (SiO₂).

The conductive layer 923 functions as, for example, a gate electrode of the read transistor RTr (FIG. 96) and the sense node SN (FIG. 96). The conductive layer 933 functions as, for example, a gate electrode of the switch transistor STr (FIG. 96) and a part of the read word line RWL (FIG. 96). The conductive layers 923, 933 contain, for example, an electrically conductive material, such as titanium nitride (TiN), or a conductive oxide, such as indium tin oxide (ITO). The conductive layer 923 is opposed to the upper surface, the lower surface, both side surfaces in the Y-direction, and the side surface on the one side (the transistor structure 910 side) in the X-direction, of the semiconductor portion 921 via the insulating portion 922. The conductive layer 933 is opposed to the upper surface, the lower surface, both side surfaces in the Y-direction, and the side surface on the other side (opposite side of the transistor structure 910) in the X-direction, of the semiconductor portion 931 via the insulating portion 932.

The semiconductor memory device according to the ninth embodiment may include the wiring member 320 (FIG. 68) or the wiring member 520 (FIG. 74, FIG. 75) instead of the wiring member 120.

The semiconductor memory device according to the ninth embodiment may include the via-wiring 204 and the transistor structure 210 (FIG. 65-FIG. 67) or the transistor structure 610 (FIG. 91-FIG. 93) instead of the via-wiring 901 and the transistor structure 910. The semiconductor memory device according to the ninth embodiment may include a via-wiring having a structure similar to that of the via-wiring 204 and a transistor structure having a structure similar to that of the transistor structure 210 (FIG. 65-FIG. 67) or the transistor structure 610 (FIG. 91-FIG. 93) instead of the via-wiring 903 and the transistor structure 930.

In the ninth embodiment, the side surface of the conductive layer 113 and the side surface of the wiring member 120 connected to the conductive layer 113 on one side in the X-direction (X-direction negative side in FIG. 97) are disposed on the other side in the X-direction (X-direction positive side in FIG. 97) with respect to the end portion of the via-wiring 901 on the one side in the X-direction (X-direction negative side in FIG. 97). However, the side surface of the conductive layer 113 and the side surface of the wiring member 120 connected to the conductive layer 113 on the one side in the X-direction (X-direction negative side in FIG. 97) may be disposed on the one side in the X-direction (X-direction negative side in FIG. 97) with respect to the end portion of the via-wiring 901 on the one side in the X-direction (X-direction negative side in FIG. 97).

Similarly, in the ninth embodiment, the side surface of the conductive layer 933 and the side surface of the wiring member 120 connected to the conductive layer 933 on the other side in the X-direction (X-direction positive side in FIG. 97) are disposed on the one side in the X-direction (X-direction negative side in FIG. 97) with respect to the end portion of the via-wiring 903 on the other side in the X-direction (X-direction positive side in FIG. 97). However, the side surface of the conductive layer 933 and the side surface of the wiring member 120 connected to the conductive layer 933 on the other side in the X-direction (X-direction positive side in FIG. 97) may be disposed on the other side in the X-direction (X-direction positive side in FIG. 97) with respect to the end portion of the via-wiring 903 on the other side in the X-direction (X-direction positive side in FIG. 97).

### Other Embodiments

The semiconductor memory devices according to the first embodiment to the ninth embodiment are described above. However, the semiconductor memory devices according to these embodiments are merely examples, and the specific configuration and the like can be adjusted as appropriate.

For example, in the semiconductor memory devices according to the first embodiment to the ninth embodiment, the via-wiring 104 and the like that function as the bit line BL and the like contain the conductive oxide, such as indium tin oxide (ITO). However, such a conductive oxide may be contained in not the via-wiring 104 and the like extending in the Z-direction but the transistor structure 110 and the like. The via-wiring 104 and the like and the transistor structure 110 and the like may contain another material and the like.

In the semiconductor memory devices according to the first embodiment to the ninth embodiment, the conductive layer 113 and the like that function as the gate electrode of the transistor TrC and the like may be opposed to only one of the upper surface and the lower surface of the semiconductor layer 111 and the like that function as the channel region of the transistor TrC and the like.

In the first embodiment to the eighth embodiment, an example in which the capacitor CpC is employed as the memory portion connected to the transistor structure 110 and the like is described. In the ninth embodiment, an example in which the sense node SN is employed as the memory portion connected to the transistor structure 910 is described. However, the memory portion does not need to be the capacitor CpC. For example, the memory portion may contain a ferroelectric material, a ferromagnet material, a chalcogen material such as GeSbTe, or another material and may store data using the characteristics of these materials. For example, in any of the structures described above, any of these materials may be contained in the insulating layer between the electrodes forming the capacitor CpC.

The methods of manufacturing the semiconductor memory devices described above also can be adjusted as appropriate. For example, the order of any two processes in the above-described processes may be changed, or any two processes in the above-described processes may be simultaneously performed.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of semiconductor layers stacked in a first direction and arranged in a second direction intersecting with the first direction and a third direction intersecting with the first direction and the second direction;
a plurality of via-wirings arranged in the second direction and the third direction, extending in the first direction, and each electrically connected to the plurality of semiconductor layers stacked in the first direction;
a plurality of memory portions stacked in the first direction, arranged in the second direction and the third direction, and electrically connected to the respective plurality of semiconductor layers;
a plurality of gate electrodes stacked in the first direction, arranged in the second direction and the third direction, and opposed to the respective plurality of semiconductor layers; and
a plurality of wiring members stacked in the first direction, arranged in the second direction and the third direction, and each disposed between two gate electrodes adjacent in the third direction among the plurality of gate electrodes, wherein
the plurality of gate electrodes include a plurality of first gate electrodes disposed at a first position in the first direction and arranged in the third direction,
the plurality of wiring members include a plurality of first wiring members disposed at the first position in the first direction and arranged in the third direction, and
the plurality of first wiring members are mutually electrically connected via the plurality of first gate electrodes.

2. The semiconductor memory device according to claim 1, comprising
an insulating layer extending in the first direction and the third direction, wherein
the plurality of via-wirings include a first via-wiring and a second via-wiring adjacent in the second direction via the insulating layer, and
the first via-wiring is spaced from the second via-wiring via the insulating layer.

3. The semiconductor memory device according to claim 2, wherein
one of the plurality of semiconductor layers is electrically connected to the first via-wiring,
one of the plurality of gate electrodes is opposed to the one of the plurality of semiconductor layers,
one of the plurality of wiring members is connected to the one of the plurality of gate electrodes, and
side surfaces of the one of the plurality of gate electrodes and the one of the plurality of wiring members on an insulating layer side in the second direction are disposed on an opposite side of the insulating layer in the second direction with respect to an end portion of the first via-wiring on the insulating layer side in the second direction.

4. The semiconductor memory device according to claim 2, wherein
one of the plurality of semiconductor layers is electrically connected to the first via-wiring,
one of the plurality of gate electrodes is opposed to the one of the plurality of semiconductor layers,
one of the plurality of wiring members is connected to the one of the plurality of gate electrodes, and
side surfaces of the one of the plurality of gate electrodes and the one of the plurality of wiring members on an insulating layer side in the second direction are disposed on the insulating layer side in the second direction with respect to an end portion of the first via-wiring on the insulating layer side in the second direction.

5. The semiconductor memory device according to claim 1, wherein
each of the plurality of via-wirings is electrically connected to two semiconductor layers adjacent in the second direction.

6. The semiconductor memory device according to claim 1, wherein
each of the plurality of wiring members is in contact with two gate electrodes adjacent in the third direction among the plurality of gate electrodes.

7. The semiconductor memory device according to claim 1, wherein
each of the plurality of wiring members is in contact with side surfaces of two gate electrodes in the third direction, the two gate electrodes being adjacent in the third direction among the plurality of gate electrodes.

8. The semiconductor memory device according to claim 1, wherein
each of the plurality of wiring members is in contact with each side surface of two gate electrodes in the second direction, the two gate electrodes being adjacent in the third direction among the plurality of gate electrodes.

9. The semiconductor memory device according to claim 1, wherein
each of the plurality of wiring members is continuous with each of two gate electrodes adjacent in the third direction among the plurality of gate electrodes.

10. The semiconductor memory device according to claim 9, comprising:
a plurality of gate insulating films stacked in the first direction, arranged in the second direction and the third direction, and each disposed between one of the plurality of semiconductor layers and one of the plurality of gate electrodes; and
a plurality of insulating members stacked in the first direction, arranged in the second direction and the third direction, and each continuous with two gate insulating films adjacent in the third direction among the plurality of gate insulating films, wherein
one of the plurality of wiring members is in contact with surfaces on one side and the other side in the first direction and both side surfaces in the second direction, of one of the plurality of insulating members.

11. The semiconductor memory device according to claim 1, wherein
each of the plurality of semiconductor layers contains at least one element of gallium (Ga) or aluminum (Al) and contains indium (In), zinc (Zn), and oxygen (O).

12. The semiconductor memory device according to claim 1, wherein
the plurality of memory portions are plurality of capacitors.

13. The semiconductor memory device according to claim 1, comprising:
a plurality of other gate electrodes stacked in the first direction, arranged in the second direction and the third direction, and electrically connected to the respective plurality of semiconductor layers;
a plurality of other semiconductor layers stacked in the first direction, arranged in the second direction and the third direction, and opposed to the respective plurality of other gate electrodes; and
a plurality of other via-wirings arranged in the second direction and the third direction, extending in the first direction, and electrically connected to the respective plurality of other semiconductor layers stacked in the first direction, wherein
the plurality of memory portions are the plurality of other gate electrodes.

14. The semiconductor memory device according to claim 1, wherein
at least a part of one of the plurality of first wiring members overlaps with one of the plurality of via-wirings when viewed in the third direction.

15. A semiconductor memory device comprising:
a plurality of semiconductor layers stacked in a first direction and arranged in a second direction intersecting with the first direction;
a plurality of via-wirings arranged in the second direction, extending in the first direction, and each electrically connected to the plurality of semiconductor layers stacked in the first direction;
a plurality of memory portions stacked in the first direction, arranged in the second direction, and electrically connected to the respective plurality of semiconductor layers;
a plurality of gate electrodes stacked in the first direction, arranged in the second direction, and opposed to the respective plurality of semiconductor layers; and
a plurality of wiring members stacked in the first direction, arranged in the second direction, extending in a third direction intersecting with the first direction and the second direction, and continuous with the respective plurality of gate electrodes, wherein
a length of the plurality of wiring members in the first direction is smaller than a length of the plurality of gate electrodes in the first direction.

16. The semiconductor memory device according to claim 15, comprising
an insulating layer extending in the first direction, wherein
the plurality of via-wirings include a first via-wiring and a second via-wiring adjacent in the second direction via the insulating layer, and
the first via-wiring is spaced from the second via-wiring via the insulating layer.

17. The semiconductor memory device according to claim 16, wherein
one of the plurality of semiconductor layers is electrically connected to the first via-wiring,
one of the plurality of gate electrodes is opposed to the one of the plurality of semiconductor layers,
one of the plurality of wiring members is continuous with the one of the plurality of gate electrodes, and
side surfaces of the one of the plurality of gate electrodes and the one of the plurality of wiring members on an insulating layer side in the second direction are disposed on an opposite side of the insulating layer in the second direction with respect to an end portion of the first via-wiring on the insulating layer side in the second direction.

18. The semiconductor memory device according to claim 16, wherein
one of the plurality of semiconductor layers is electrically connected to the first via-wiring,
one of the plurality of gate electrodes is opposed to the one of the plurality of semiconductor layers,
one of the plurality of wiring members is continuous with the one of the plurality of gate electrodes, and
side surfaces of the one of the plurality of gate electrodes and the one of the plurality of wiring members on an insulating layer side in the second direction are disposed on the insulating layer side in the second direction with respect to an end portion of the first via-wiring on the insulating layer side in the second direction.

19. The semiconductor memory device according to claim 15, wherein
each of the plurality of via-wirings is electrically connected to two semiconductor layers adjacent in the second direction.

20. The semiconductor memory device according to claim 15, comprising:
a plurality of gate insulating films stacked in the first direction, arranged in the second direction, and each disposed between one of the plurality of semiconductor layers and one of the plurality of gate electrodes; and
a plurality of insulating members stacked in the first direction corresponding to the plurality of gate insulating films, arranged in the second direction, extending in the third direction, and each continuous with corresponding one of the plurality of gate insulating films, wherein
one of the plurality of wiring members is in contact with surfaces on one side and the other side in the first direction and both side surfaces in the second direction, of one of the plurality of insulating members.

21. The semiconductor memory device according to claim 15, wherein
at least a part of one of the plurality of wiring members overlaps with one of the plurality of via-wirings when viewed in the third direction.

22. The semiconductor memory device according to claim 15, wherein
each of the plurality of semiconductor layers contains at least one element of gallium (Ga) or aluminum (Al) and contains indium (In), zinc (Zn), and oxygen (O).
